(19) United States
(12) Patent Application Publication
(10) Pub. No.: US 2026/0107544 A1
(43) Pub. Date: Apr. 16, 2026

(54) BACKSIDE CONTACT AND BACKSIDE ISOLATION

(71) Applicant: International Business Machines Corporation, Armonk, NY (US)

(72) Inventors: Huimei Zhou, Albany, NY (US); Ravikumar Ramachandran, Pleasantville, NY (US); Xiaoming Yang, Clifton Park, NY (US); Ruilong Xie, Niskayuna, NY (US); Mahender Kumar, Clifton Park, NY (US); Reinaldo Vega, Mahopac, NY (US)

(21) Appl. No.: 18/915,477

(22) Filed: Oct. 15, 2024

(51) Int. Cl. H01L 29/417; H01L 21/768; H01L 29/06; H01L 29/423; H01L 29/66; H01L 29/775; H01L 29/786

(52) U.S. Cl. CPC H10D 64/254; H10D 30/014; H10D 30/43; H10D 30/6219; H10D 30/6757; H10D 62/10; H10W 20/069; H10W 20/076; H10D 30/6735; H10D 62/121

(57) ABSTRACT

Embodiments relate to backside contact and backside isolation. An aspect includes a semiconductor structure having channel regions connected to a first source/drain region and a second source/drain region and a backside contact disposed under the first source/drain region. An aspect includes a liner vertically extending from a backside of the second source/drain region, the liner protecting the backside of the second source/drain region from contact with the backside contact.

The following disclosure is submitted under 35 U.S.C. 102(b)(1)(A):

DISCLOSURE(S): “Backside Power Distribution for Nanosheet Technologies Beyond 2 nm,” by Huimei Zhou, Ravikumar Ramachandran, Xiaoming Yang, Ruilong Xie, Mahender Kumar, Reinaldo Vega, presented Jun. 16-20, 2024 at the 2024 IEEE Symposium on VLSI Technology and Circuits.

### BACKGROUND

The present invention generally relates to fabrication methods and resulting structures for integrated circuits (ICs), and more specifically, to fabrication methods and resulting structures configured and arranged to provide backside contacts and backside isolation.

ICs (also referred to as a chip or a microchip) include electronic circuits on a wafer. The wafer is a semiconductor material, such as, for example, silicon or other materials. An IC is formed of a large number of devices, such as transistors, capacitors, resistors, etc., which are formed in layers of the IC and interconnected with wiring in the back-end-of-line (BEOL) layers of the wafer. on the wafer. Typical ICs are formed by first fabricating individual semiconductor devices using processes referred to generally as the front-end-of-line (FEOL). A metal-oxide-semiconductor field-effect transistor (MOSFET) is a transistor used for amplifying or switching electronic signals. The MOSFET has a source, a drain, and a metal oxide gate electrode. A conventional FET is a planar device where the entire channel region of the device is formed parallel and slightly below the planar upper surface of the semiconducting substrate. In contrast to a planar FET, there are so-called three-dimensional (3D) devices, such as a FinFET device, which is a three-dimensional structure. One type of device for advanced integrated circuit products is generally known as a nanosheet transistor. In general, a nanosheet transistor has a fin-type channel structure that includes a plurality of vertically spaced-apart sheets of semiconductor material. A gate structure for the device is positioned around each of these spaced-apart layers of channel semiconductor material.

### SUMMARY

Embodiments of the present invention are directed to providing backside contacts with backside isolation. A semiconductor structure includes channel regions connected to a first source/drain region and a second source/drain region, and a backside contact disposed under the first source/drain region. The semiconductor structure includes a liner vertically extending from a backside of the second source/drain region, the liner protecting the backside of the second source/drain region from contact with the backside contact.

Other embodiments of the present invention implement features of the above-described devices/structures in methods and/or implement features of the methods in devices/structures.

Additional technical features and benefits are realized through the techniques of the present invention. Embodiments and aspects of the invention are described in detail herein and are considered a part of the claimed subject matter. For a better understanding, refer to the detailed description and to the drawings.

### BRIEF DESCRIPTION OF THE DRAWINGS

The specifics of the exclusive rights described herein are particularly pointed out and distinctly claimed in the claims at the conclusion of the specification. The foregoing and other features and advantages of the embodiments of the invention are apparent from the following detailed description taken in conjunction with the accompanying drawings in which:

FIGS. 1A and 1B respectively depict a top view and a cross-sectional view of a portion of an integrated circuit (IC) under-fabrication after fabrication operations according to one or more embodiments;

FIGS. 2A and 2B depict a top view and a cross-sectional view of a portion of an IC under-fabrication after fabrication operations according to one or more embodiments;

FIGS. 3A and 3B depict a top view and a cross-sectional view of a portion of an IC under-fabrication after fabrication operations according to one or more embodiments;

FIGS. 4A and 4B depict a top view and a cross-sectional view of a portion of an IC under-fabrication after fabrication operations according to one or more embodiments;

FIGS. 5A, 5B, 5C, 5D, and 5E depict a top view and cross-sectional views of a portion of an IC under-fabrication after fabrication operations according to one or more embodiments;

FIGS. 6A, 6B, 6C, 6D, and 6E depict a top view and cross-sectional views of a portion of an IC under-fabrication after fabrication operations according to one or more embodiments;

FIGS. 7A, 7B, 7C, 7D, and 7E depict a top view and cross-sectional views of a portion of an IC under-fabrication after fabrication operations according to one or more embodiments;

FIGS. 8A, 8B, 8C, 8D, and 8E depict a top view and cross-sectional views of a portion of an IC under-fabrication after fabrication operations according to one or more embodiments;

FIGS. 9A, 9B, 9C, 9D, and 9E depict a top view and cross-sectional views of a portion of an IC under-fabrication after fabrication operations according to one or more embodiments;

FIGS. 10A, 10B, 10C, 10D, and 10E depict a top view and cross-sectional views of a portion of an IC under-fabrication after fabrication operations according to one or more embodiments;

FIGS. 11A, 11B, 11C, 11D, and 11E depict a top view and cross-sectional views of a portion of an IC under-fabrication after fabrication operations according to one or more embodiments;

FIGS. 12A, 12B, 12C, 12D, and 12E depict a top view and cross-sectional views of a portion of an IC under-fabrication after fabrication operations according to one or more embodiments;

FIGS. 13A, 13B, 13C, 13D, and 13E depict a top view and cross-sectional views of a portion of an IC under-fabrication after fabrication operations according to one or more embodiments;

FIGS. 14A, 14B, 14C, 14D, and 14E depict a top view and cross-sectional views of a portion of an IC under-fabrication after fabrication operations according to one or more embodiments;

FIGS. 15A, 15B, 15C, 15D, and 15E depict a top view and cross-sectional views of a portion of an IC under-fabrication after fabrication operations according to one or more embodiments;

FIGS. 16A, 16B, 16C, 16D, and 16E depict a top view and cross-sectional views of a portion of an IC under-fabrication after fabrication operations according to one or more embodiments;

FIGS. 17A, 17B, 17C, 17D, and 17E depict a top view and cross-sectional views of a portion of an IC under-fabrication after fabrication operations according to one or more embodiments;

FIGS. 18A, 18B, 18C, 18D, and 18E depict a top view and cross-sectional views of a portion of an IC under-fabrication after fabrication operations according to one or more embodiments;

FIGS. 19A, 19B, 19C, 19D, and 19E depict a top view and cross-sectional views of a portion of an IC under-fabrication after fabrication operations according to one or more embodiments;

FIGS. 20A, 20B, 20C, 20D, and 20E depict a top view and cross-sectional views of a portion of an IC under-fabrication after fabrication operations according to one or more embodiments;

FIG. 21 depicts a flowchart of a method of forming a semiconductor structure according to one or more embodiments; and

FIG. 22 depicts a flowchart of a method of forming a semiconductor structure according to one or more embodiments.

### DETAILED DESCRIPTION

For the sake of brevity, conventional techniques related to semiconductor device and integrated circuit (IC) fabrication may or may not be described in detail herein. Moreover, the various tasks and process steps described herein can be incorporated into a more comprehensive procedure or process having additional steps or functionality not described in detail herein. In particular, various steps in the manufacture of semiconductor devices and semiconductor-based ICs are well known and so, in the interest of brevity, many conventional steps will only be mentioned briefly herein or will be omitted entirely without providing the well-known process details.

The MOSFET is a transistor used for amplifying or switching electronic signals. The MOSFET has a source, a drain, and a metal gate electrode. The metal gate is electrically insulated from the main semiconductor n-channel or p-channel by a thin layer of insulating material, for example, silicon dioxide or glass, which makes the input resistance of the MOSFET relatively high. The gate voltage controls whether the current path from the source to the drain is an open circuit (“off”) or a resistive path (“on”). N-type field effect transistors (NFET) and p-type field effect transistors (PFET) are two types of complementary MOSFETs. The NFET includes n-doped source and drain junctions and uses electrons as the current carriers. The PFET includes p-doped source and drain junctions and uses holes as the current carriers.

The nanowire or nanosheet MOSFET is a type of MOSFET that uses multiple stacked nanowires/nanosheets to form multiple channel regions. The gate regions of a nanosheet MOSFET are formed by wrapping gate stack materials around the multiple nanowire/nanosheet channels. This configuration is known as a gate-all-around (GAA) FET structure. The nanowire/nanosheet MOSFET device mitigates the effects of short channels and reduces drain-induced barrier lowering.

The GAA nanosheet FET structures can provide superior electrostatics. In contrast to known Fin-type FET (FinFET) structures in which the fin element of the transistor extends “up” out of the transistor, nanosheet FET designs implement the fin as a silicon nanosheet/nanowire. In a known configuration of a GAA nanosheet FET, a relatively small FET footprint is provided by forming the channel region as a series of nanosheets (i.e., silicon nanowires). A GAA configuration includes a source region, a drain region, and stacked nanosheet channels between the source and drain regions. A gate surrounds the stacked nanosheet channels and regulates electron flow through the nanosheet channels between the source and drain regions. GAA nanosheet FETs are fabricated by forming alternating layers of channel nanosheets and sacrificial nanosheets. The sacrificial nanosheets are released from the channel nanosheets before the FET device is finalized.

Another nonplanar transistor architecture is the so-called stacked field effect transistor (FET). To increase the available computing power per unit area, a stacked FET (or SFETs) a vertical stack of two (or more) FETs over a shared substrate footprint. As one fabrication technique, two wafers are processed separately (i.e., semiconductor stacks are built on each wafer) and later joined via a wafer bonding process. The resultant stacked transistor architecture offers several improvements over planar and fin-type devices, such as the ability to build complementary devices (e.g., CMOS) at a reduced footprint. Although fabrication of stacked FETs may be challenging, efforts are ongoing to design stacked FET fabrication schemes and structures that are suitable for scaled production.

Current fabrication methods for ICs may face challenges in achieving efficient backside contacts and isolation. The complexity of modern ICs, which include multiple layers and intricate structures, often leads to difficulties in maintaining alignment and preventing short circuits. These issues become more pronounced as device dimensions shrink, requiring more precise control over fabrication processes. Existing solutions often rely on placeholder techniques to open direct backside contacts (DBC). These methods frequently result in V-shaped etches that reduce the contact area, negatively impacting resistance-capacitance (RC) characteristics. Also, misalignment during fabrication can lead to shorts and leaks, particularly between the DBC to other backside contacts or source/drain regions.

One or more embodiments provide semiconductor structures that address these challenges by introducing a novel approach to backside contact and isolation. The structure incorporates isolation between DBCs, effectively mitigating the risk of shorts and leaks due to misalignment. By utilizing a process that allows selective retention of insulators between DBCs, the structure maintains optimal contact area and enhances RC performance. In one or more embodiments, there could be one DBC under a source/drain with direct contact to silicon and insulator under another source/drain. For example, there may be an insulator under a source/drain with sidewall isolation or with partial sidewall isolation to an adjacent DBC. Also, one source/drain can be at a different height from another source/drain. It can be seen that this approach provides a robust technical solution to the alignment and isolation issues in current IC fabrication techniques.

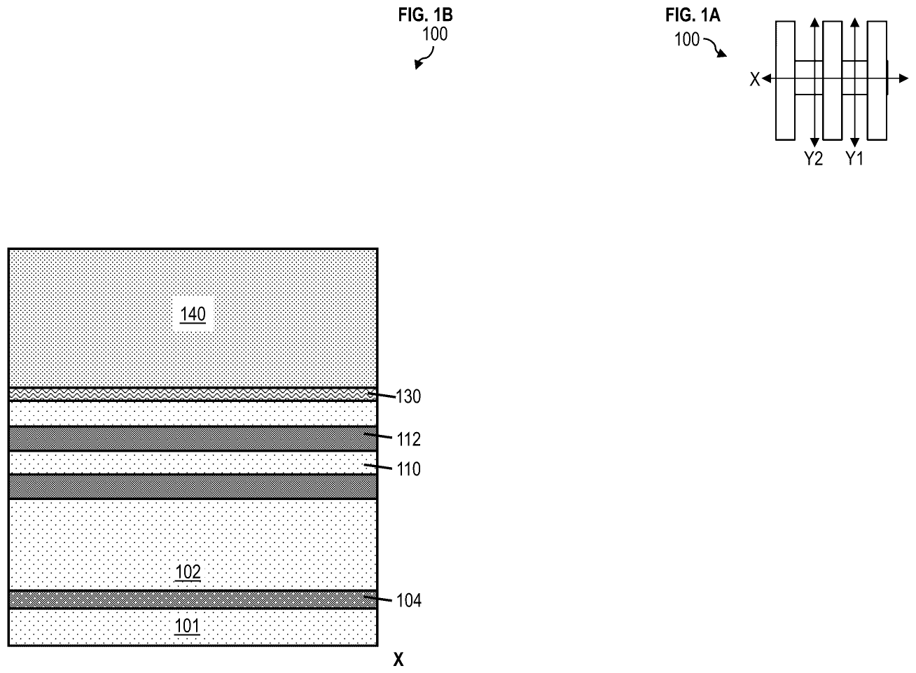

Turning now to a more detailed description of aspects of the present invention, FIG. 1A depicts a top view of a simplified illustration of a portion of an integrated circuit (IC) 100, and FIG. 1B depicts a cross-sectional view taken along X of the IC 100. For ease of understanding, some layers may be omitted from the top view so as not to obscure the figure and to view layers underneath. The top view is intended to provide a simplified illustration and a general orientation, but the top view is not intended to be a complete representation of the device. Future locations of layers may be depicted in the top view to assist the reader. Standard semiconductor fabrication techniques can be utilized to fabricate the IC 100 as understood by one of ordinary skill in the art. Any suitable lithography processes including deposition techniques and etching techniques can be utilized herein.

FIGS. 1A and 1B depict the IC 100 having a wafer where several known fabrication processes have been performed. A substrate 102 is over a lower substrate 101 with an (intervening) etch stop layer 104 in between. The substrate 102, lower substrate 101, and semiconductor layers 110 may be formed of silicon or other semiconductor materials. There are alternating nanosheets of semiconductor layers 110 and sacrificial layers 112 formed over the substrate 102. The semiconductor layers 110 are channel regions for the transistor. The sacrificial layers 112 and etch stop layer 104 are formed of silicon germanium (SiGe).

A fill layer 130 is formed on the semiconductor layers 110. The fill layer 130 may be an oxide material. For example, the fill layer 130 may include silicon dioxide, aluminum oxide, etc. A sacrificial layer 140 is formed on the fill layer 130. The sacrificial layer 140 may include amorphous silicon, polycrystalline silicon, etc.

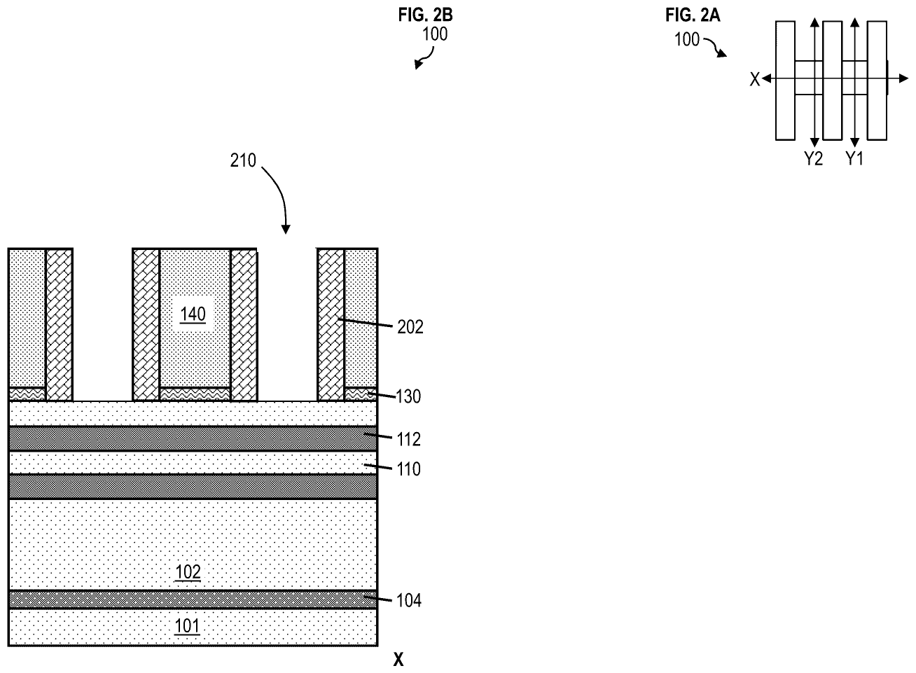

FIGS. 2A and 2B depict the IC 100 after patterning the sacrificial layer 140 and spacer deposition. Etching is performed to create openings 210 in the sacrificial layer 140 and fill layer 130, and spacer material is deposited to form spacer layers 202. A directional etch may be performed, such as reactive ion etching (RIE). A wet etch or dry etch can be utilized. Example materials of the spacer layers 202 can include SiN, SiBCN, SiOCN, SiOC, etc. Etch back can be performed to remove any excess spacer material.

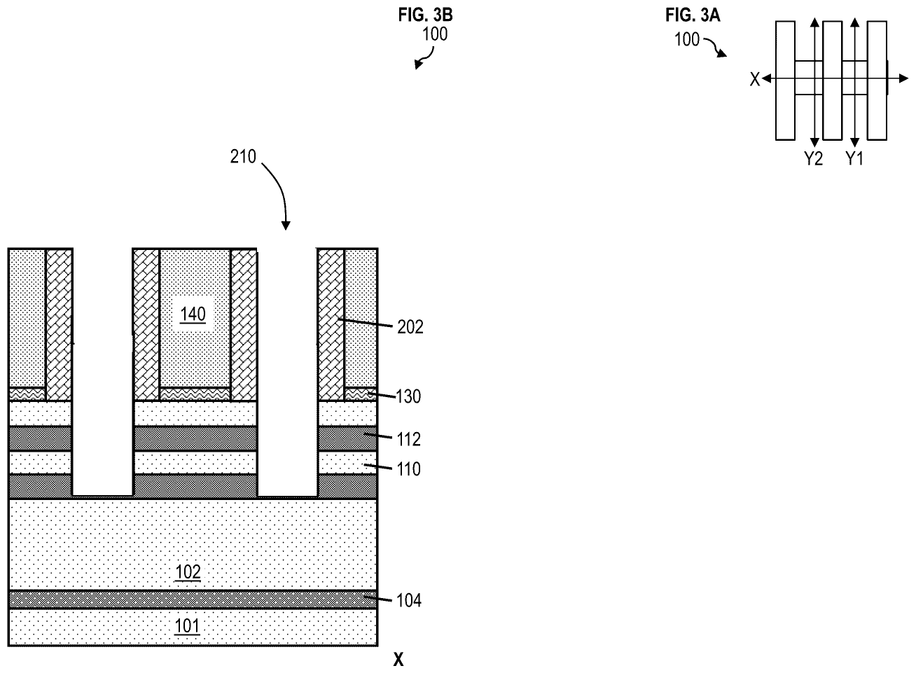

FIGS. 3A and 3B depict the IC 100 after further etching. Etching can be performed to further etch the openings 210 into the semiconductor layers 110 and sacrificial layers 112. A directional etch may be performed. A wet etch or dry etch can be utilized.

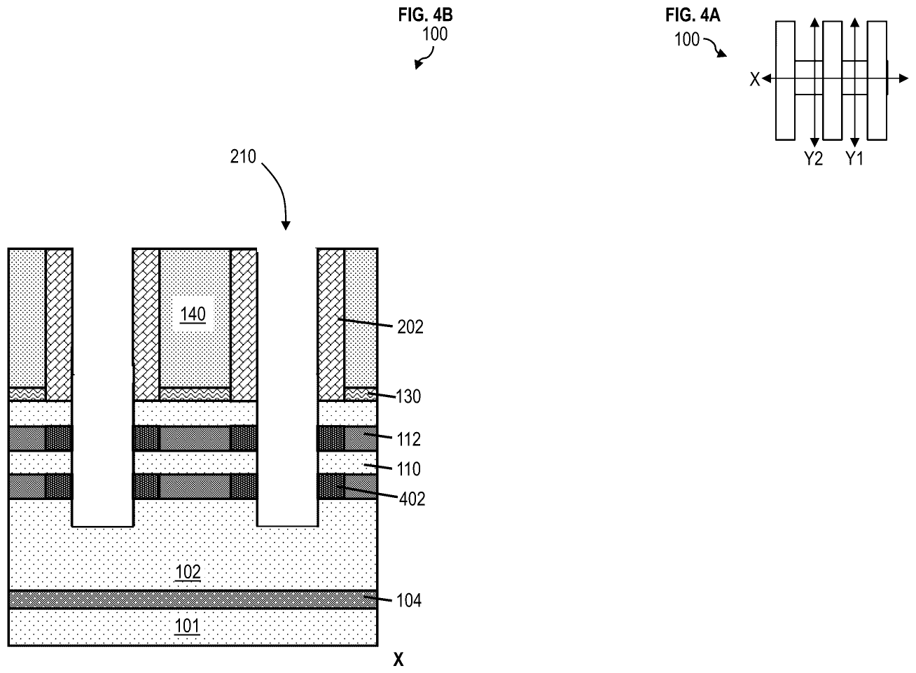

FIGS. 4A and 4B depict the IC 100 after inner spacer formation. Etching is performed to selectively etch inner spacer indentations in the exposed sides of the sacrificial layers 112, and inner spacer deposition is performed to form inner spacers 402. A wet etch or dry etch can be utilized. Example materials of the inner spacers 402 can include SiN, SiBCN, SiOCN, SiOC, etc. Etch back can be performed to remove any excess inner spacer material.

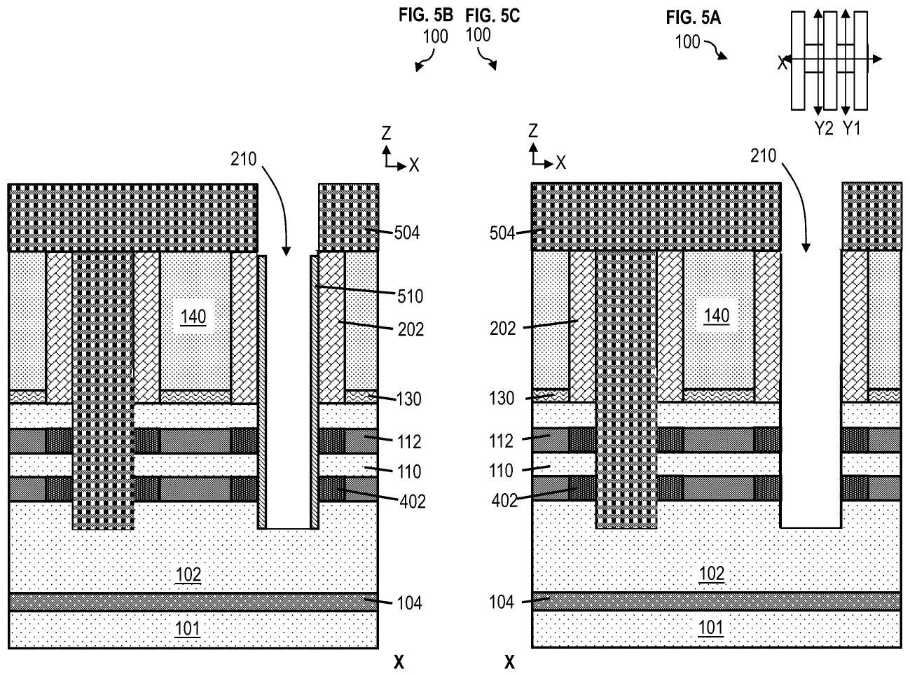

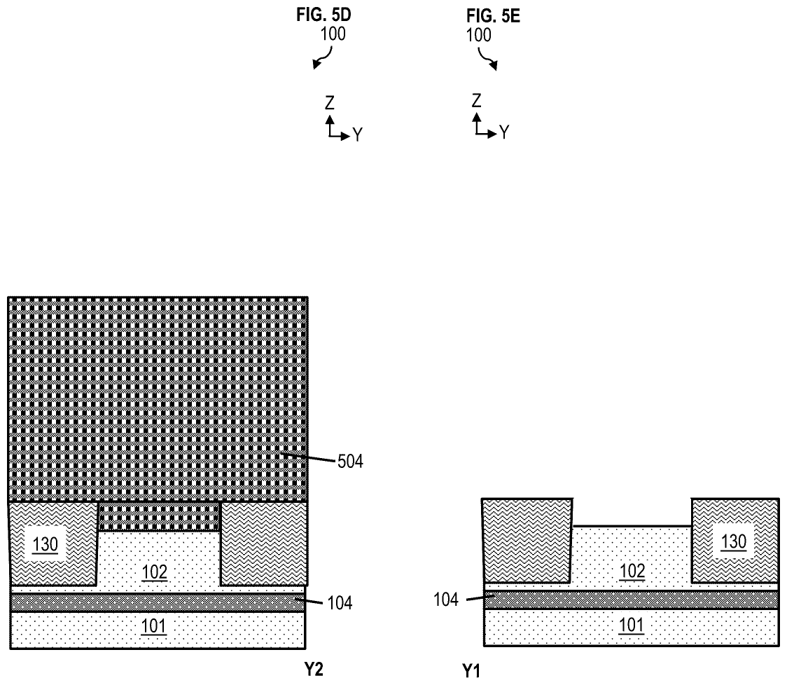

Additional views of the IC 100 are discussed along with an alternative process for the cross-sectional view taken along X. FIG. 5A depicts a top view of the IC 100, FIG. 5B depicts an alternative cross-sectional view taken along X of the IC 100, FIG. 5C depicts a cross-sectional view taken along X of the IC 100, FIG. 5D depicts a cross-sectional view taken along Y2 of the IC 100, and FIG. 5E depicts a cross-sectional view taken along Y1 of the IC 100.

A block mask 504 is formed and patterned. Example materials for the block mask 504 can include photoresist materials, silicon nitride (SiN), silicon-containing antireflective coating (SiARC), an organic planarization layer (OPL), and/or other suitable masking materials used in semiconductor fabrication to define specific areas for etching or deposition processes. Further etching is performed to increase the depth of the one of the openings 210 while another one of the openings 210 is protected by the block mask 504.

In the alternative process in FIG. 5B, a liner 510 is deposited in the opening 210, and etch back is performed. The liner 510 can be an oxide material, such as silicon dioxide, aluminum oxide, etc., and/or can be a nitride-based material that has selectivity to the material of the spacer layer 202. For example, the material of the liner 510 can be selectively etched without etching the spacer layers 202. In FIG. 5C, no liner has been formed in the opening 210 at this stage in fabrication compared to FIG. 5B.

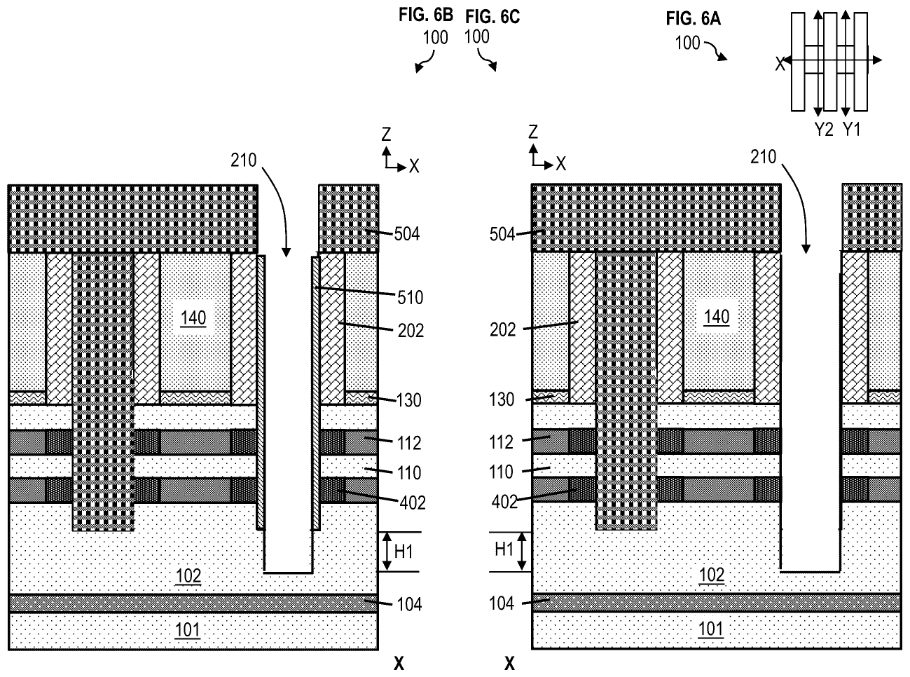

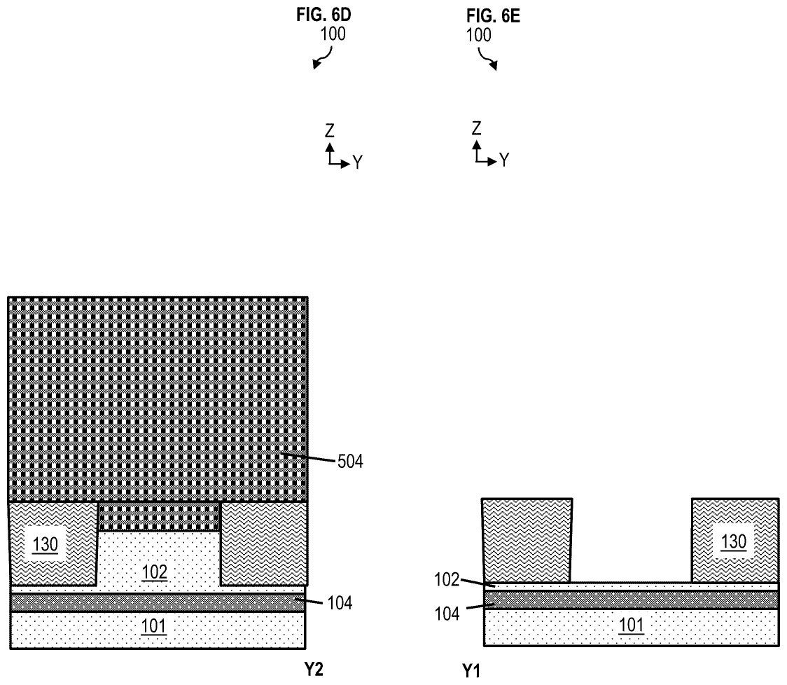

FIGS. 6A, 6B, 6C, 6D, and 6E depict the IC 100 after further etching. The opening 210 is etched further into the substrate 102. The (unprotected) opening 210 is etched a depth/height H1 greater than the (protected) opening 210 in the z-axis. A directional etch may be performed, such as a RIE etch. A wet or dry etch can be utilized.

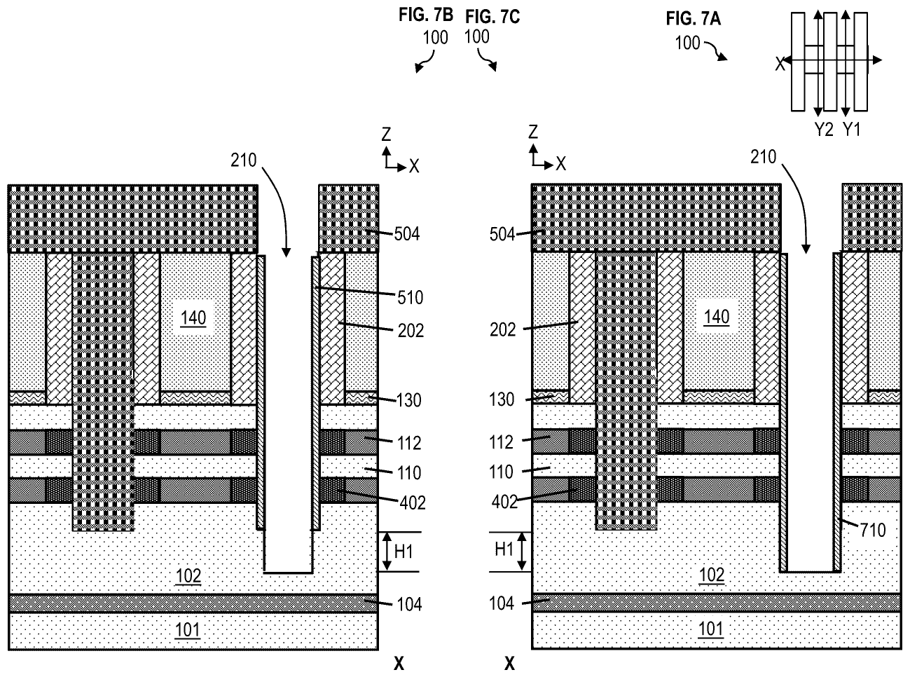

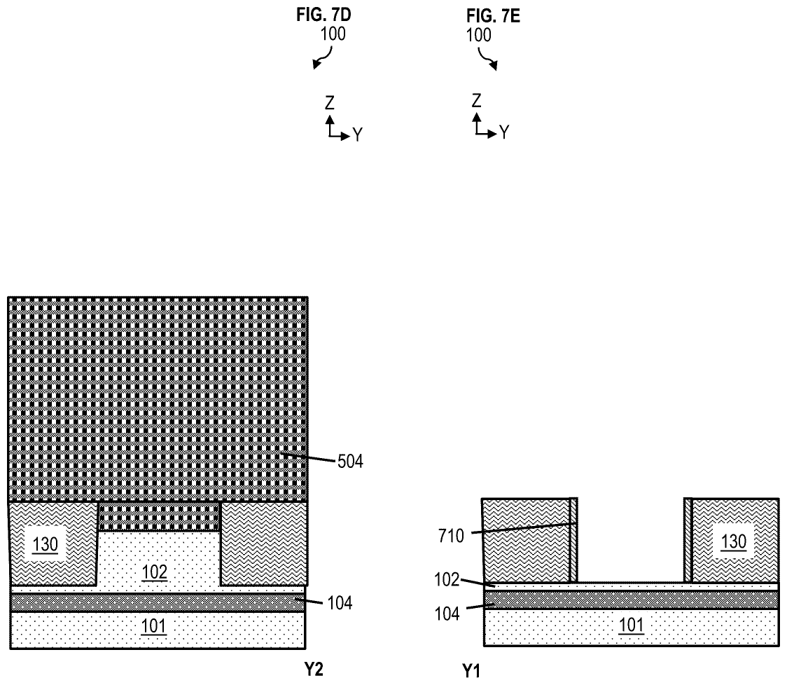

FIGS. 7A, 7B, 7C, 7D, and 7E depict the IC 100 after liner deposition. A liner 710 is deposited in the opening 210, and etch back is performed. The liner 710 is analogous to the liner 510. Because of the further etching into the substrate 102, the liner 710 extends deeper into the substrate 102 compared to the liner 510. For example, the liner 710 may have a depth/height H1 greater than the length of the liner 510 in the z-axis.

The liner 710 can be an oxide material, such as silicon dioxide, aluminum oxide, etc., and/or can be a nitride-based material that has selectivity to the material of the spacer layer 202. As noted herein, the material of the liner 710 can be selectively etched without etching the spacer layers 202.

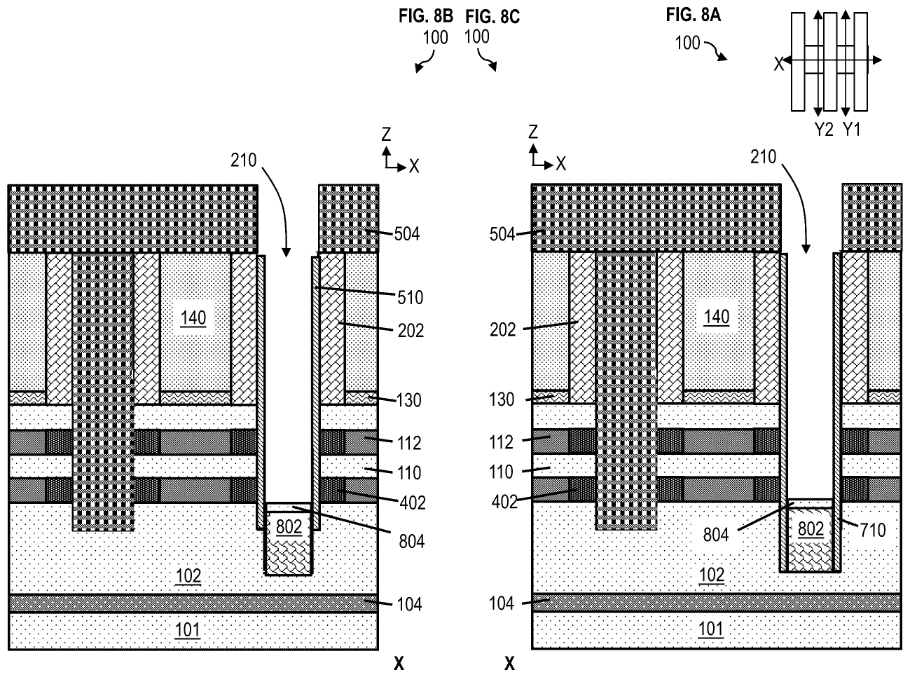

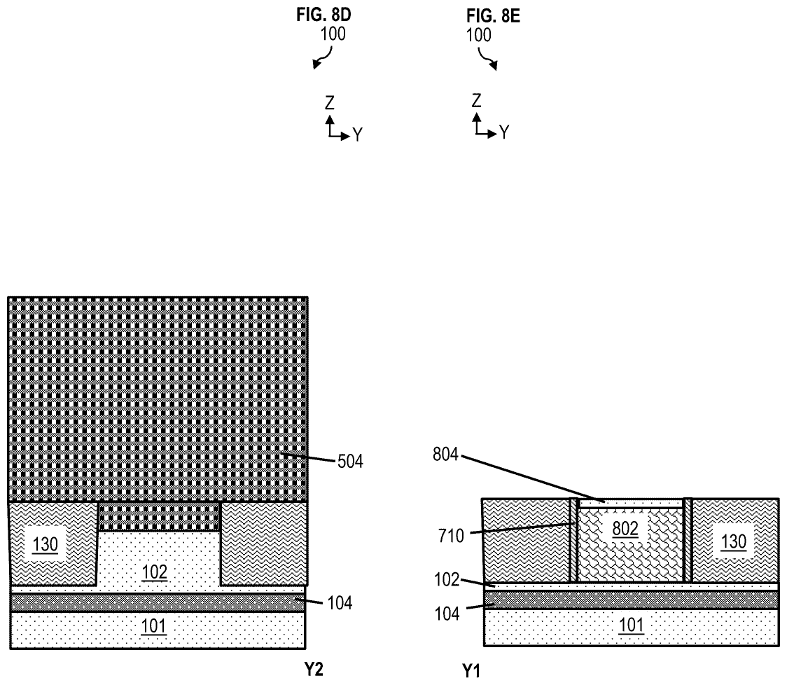

FIGS. 8A, 8B, 8C, 8D, and 8E depict the IC 100 after placeholder formation. Material is deposited to form a placeholder 802 in the opening 210. The material of the placeholder 802 may include silicon germanium or any suitable material chosen to be selectively etched in subsequent fabrication processes. Also, a layer 804 of silicon can be deposited on top of the placeholder 802 as a backside placeholder etch stopper.

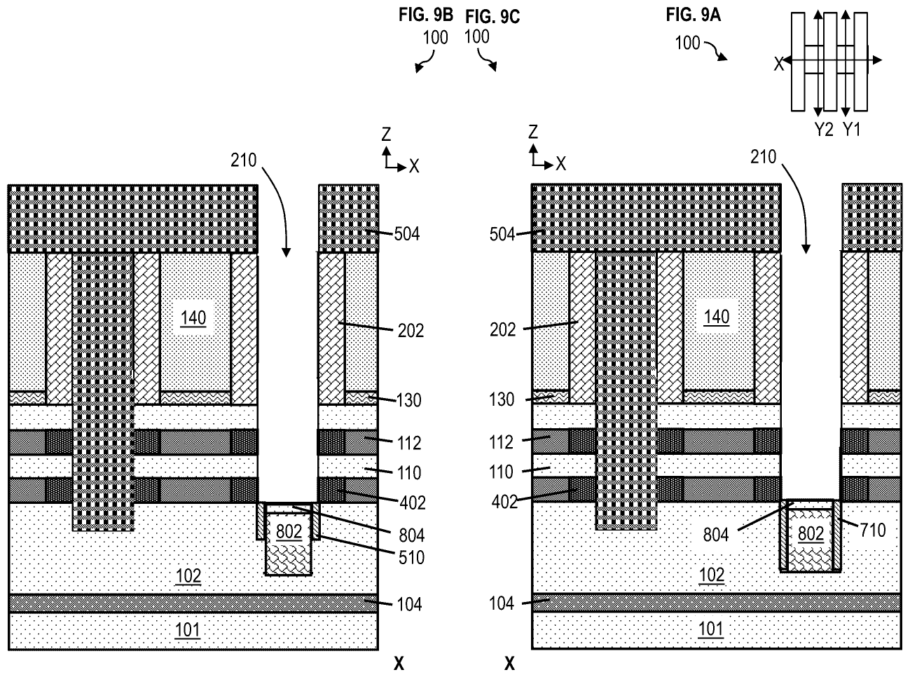

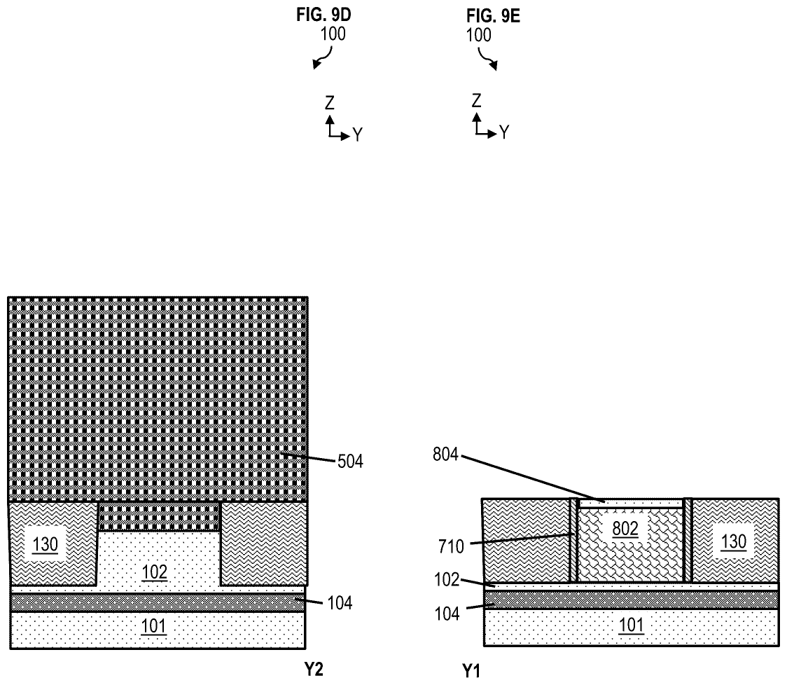

FIGS. 9A, 9B, 9C, 9D, and 9E depict the IC 100 after liner recess. The liners 510 and 710 are selectively recessed. A wet or dry etch may be used.

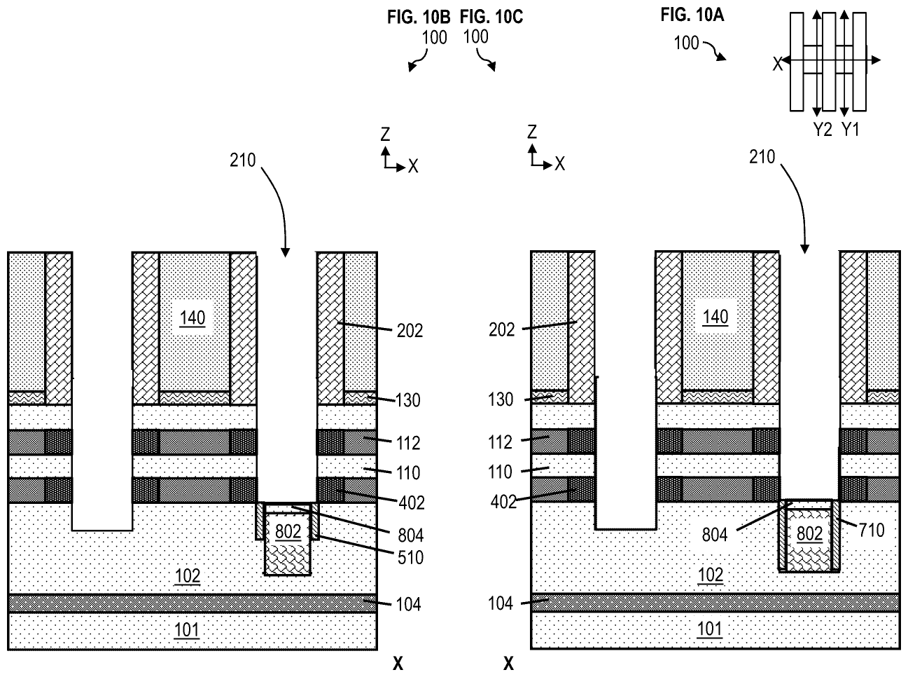

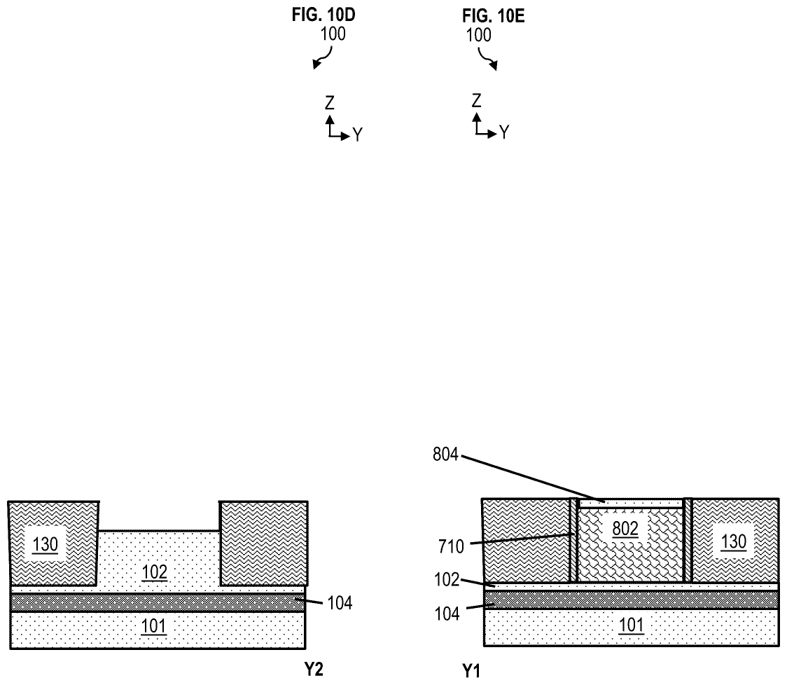

FIGS. 10A, 10B, 10C, 10D, and 10E depict the IC 100 after block mask removal. The block mask 504 is removed in preparation for epitaxial deposition. The block mask 504 can be removed using any standard technique such as, for example, ashing.

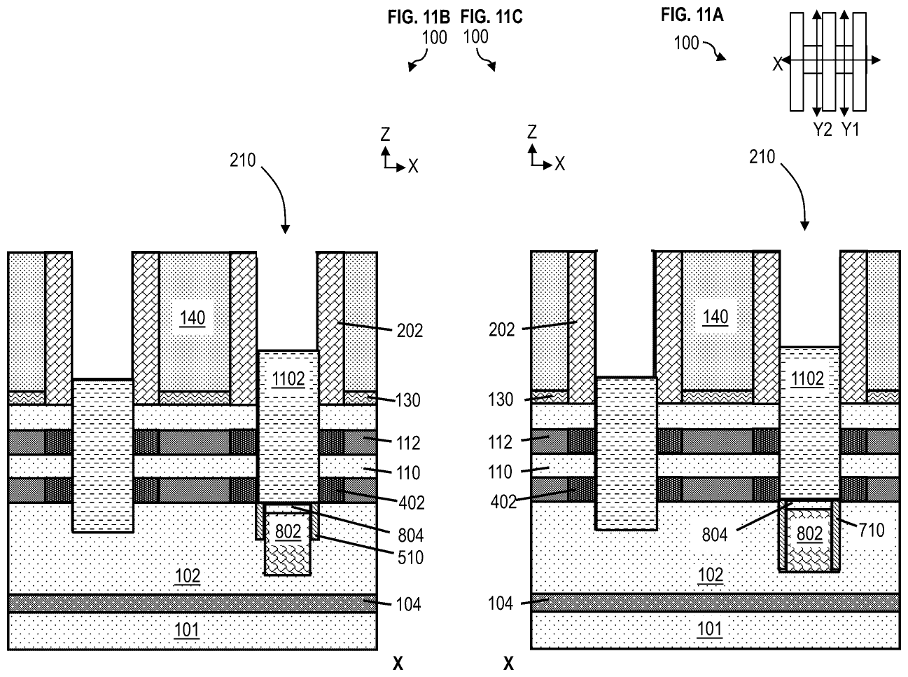

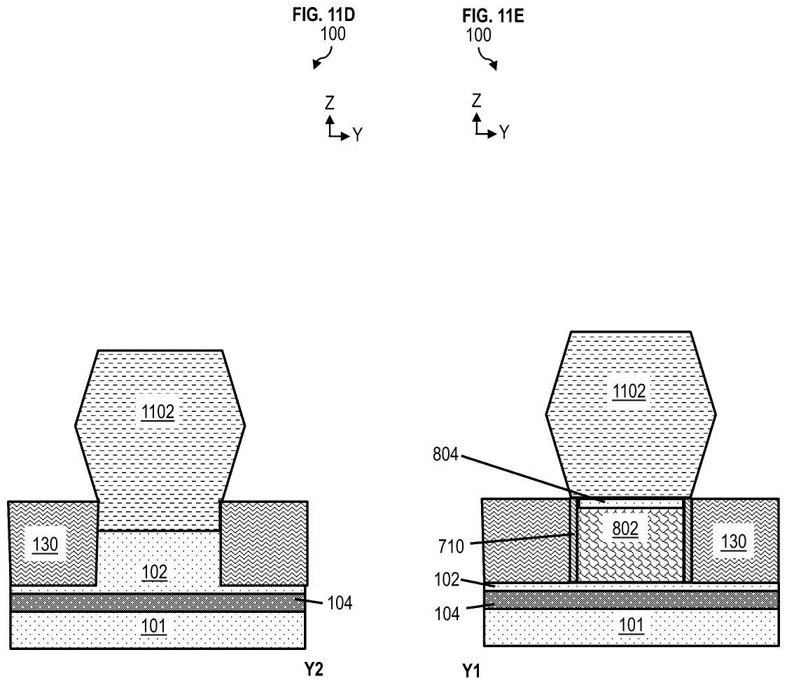

FIGS. 11A, 11B, 11C, 11D, and 11E depict the IC 100 after epitaxial growth of the source/drain regions. Source/drain regions 1102 are formed in the openings 210. One of the source/drain regions 1102 is higher than another one of the source/drain regions 1102 in the openings 210 because of the placeholder 802. For example, the source/drain region 1102 in the opening 210 with the liners 510 and 710 is at a higher level than the source/drain region 1102 in the opening 210 without the liner. The source/drain regions 1102 are connected to the semiconductor layers 110. The source/drain regions 1102 include epitaxial material that can be doped with n-type or p-type dopants according to whether an n-type or p-type transistor is formed.

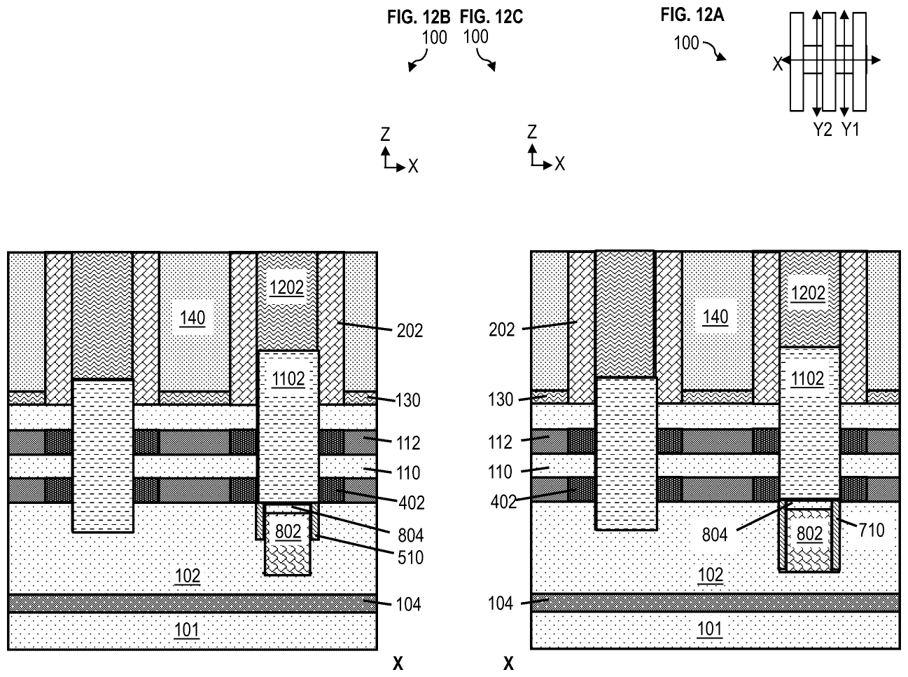

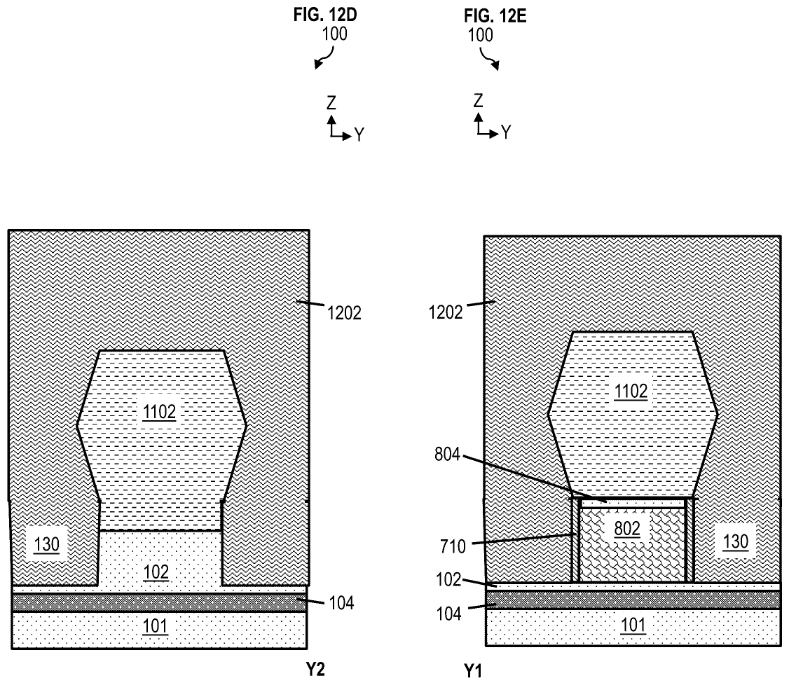

FIGS. 12A, 12B, 12C, 12D, and 12E depict the IC 100 after interlayer deposition. Interlayer/intralayer dielectric (ILD) material 1202 is formed. The ILD material 1202 can include low-k-dielectric materials, ultra-low-k dielectric materials, etc.

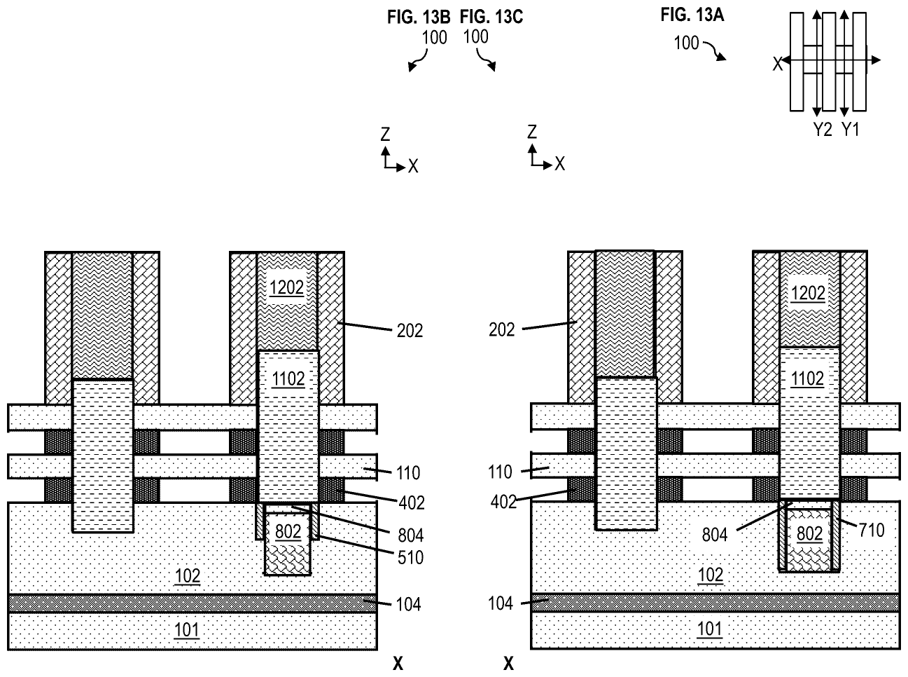

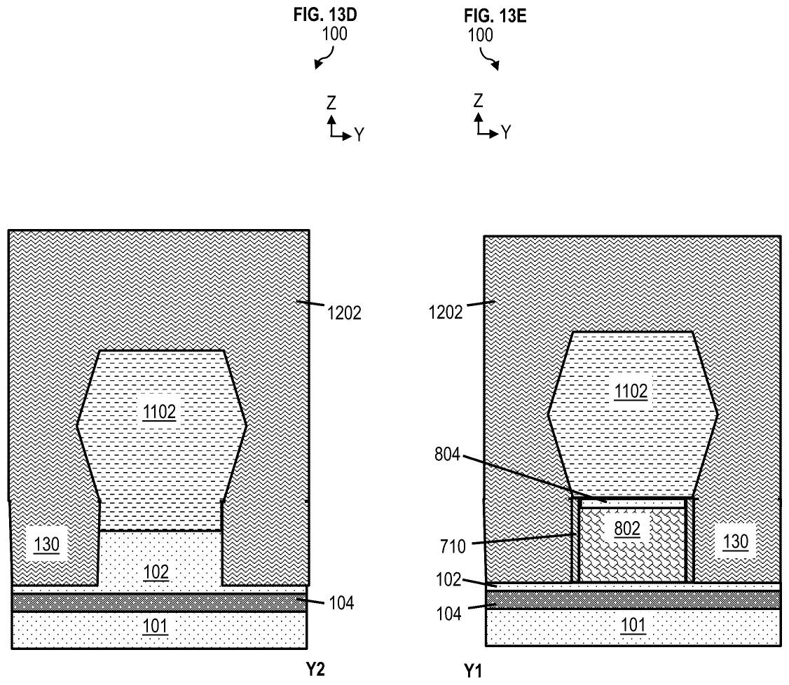

FIGS. 13A, 13B, 13C, 13D, and 13E depict the IC 100 after polysilicon pull and channel release, which begins the replacement metal gate process. The sacrificial layer 140 acting as a dummy gate is etched, and the sacrificial layers 112 are etched, thereby releasing the semiconductor layers 110.

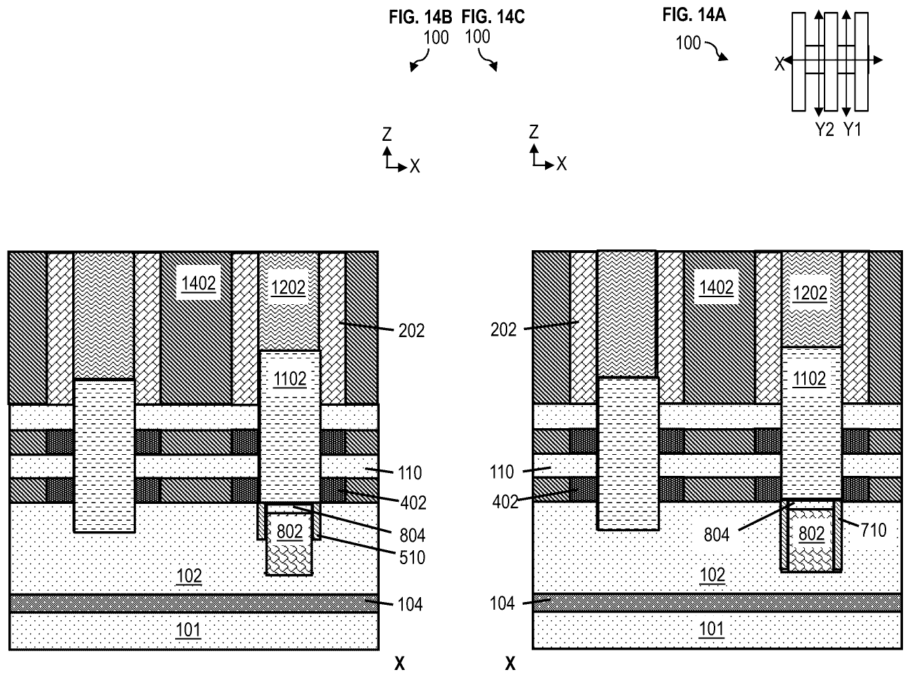

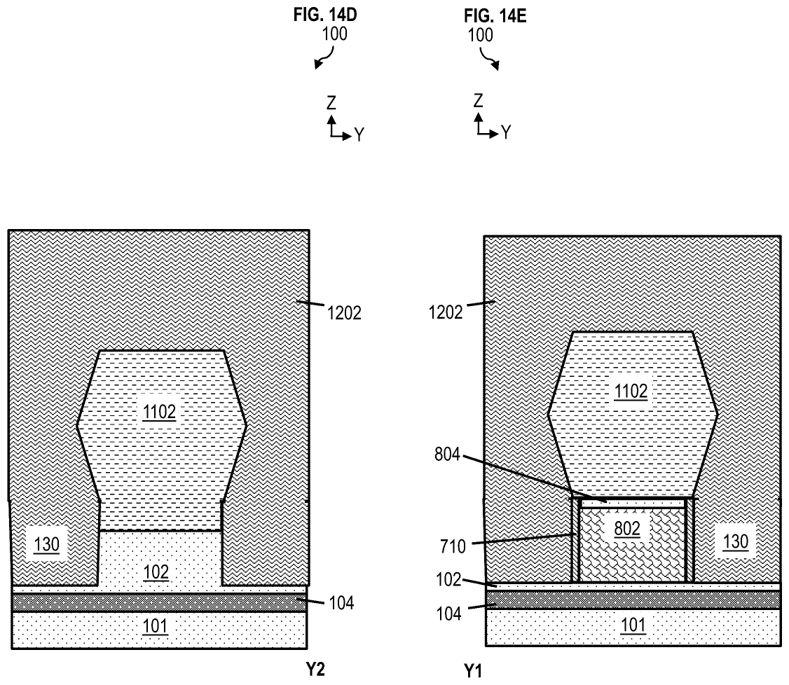

FIGS. 14A, 14B, 14C, 14D, and 14E depict the IC 100 after the replacement metal gate process. A high-k dielectric layer and work function material is deposited, resulting in a gate structure 1402. The gate structure 1402 may be referred to as a high-k metal gate or high-k metal gate stack.

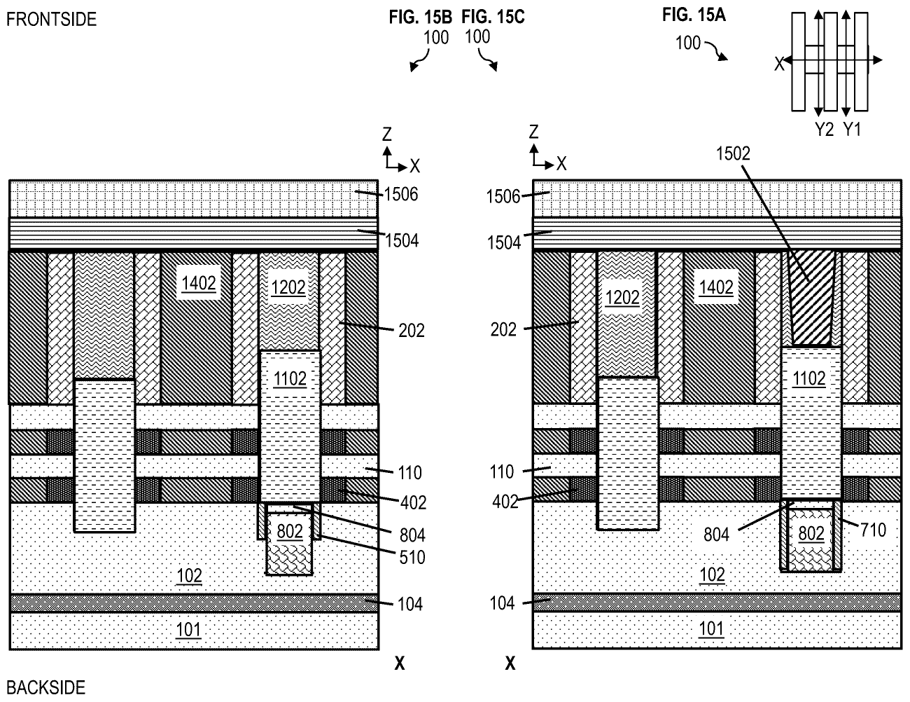

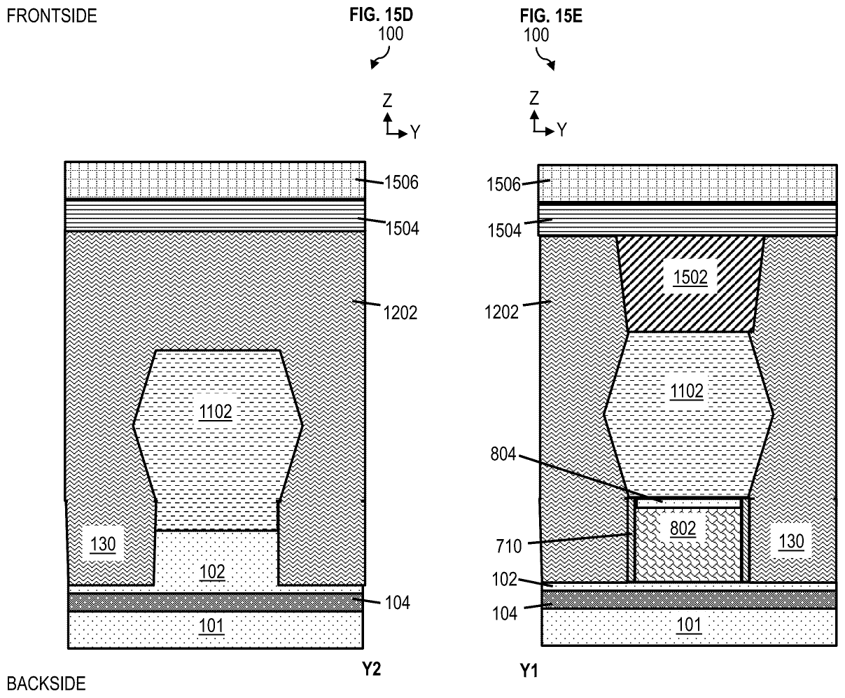

FIGS. 15A, 15B, 15C, 15D, and 15E depict the IC 100 after contact formation and back-of-line (BEOL) formation. Lithography is performed to form cavities, and conductive material is deposited to form top source/drain contacts 1502. The contacts may be referred to as metal contacts. Example conductive materials of the contacts can include tungsten, titanium, titanium nitride, aluminum, nickel, chromium, copper, gold, etc., along with various combinations and liners.

BEOL processing can be performed to form a frontside interconnect layer 1504, and a carrier wafer 1506 is bonded on the frontside interconnect layer 1504 in preparation for wafer flip. The frontside interconnect layer 1504 may represent many layers, interconnects, insulating material, etc.

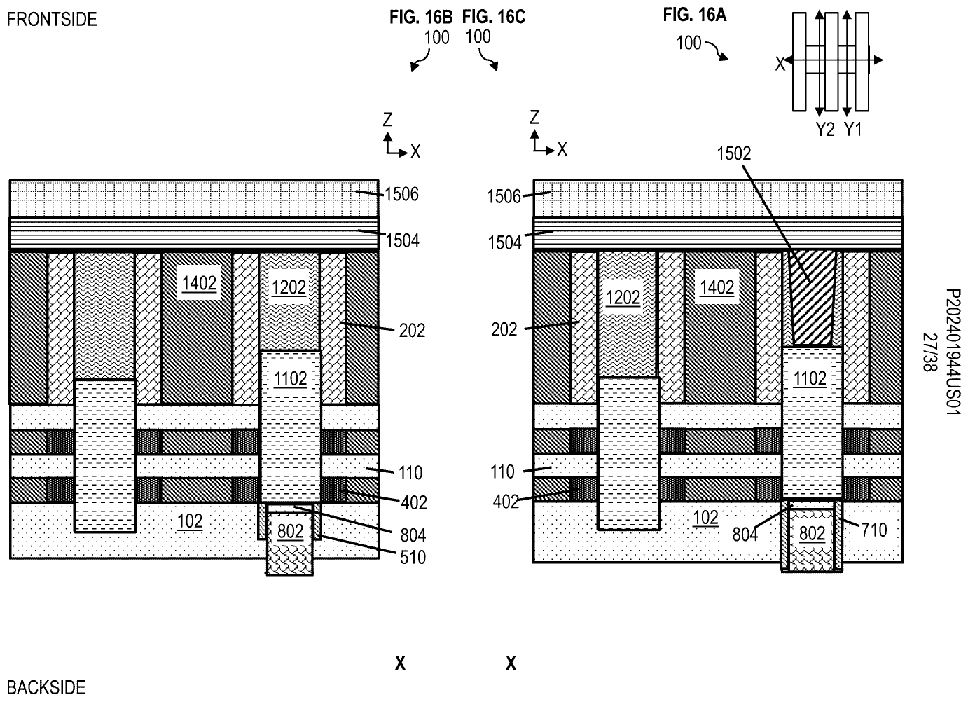

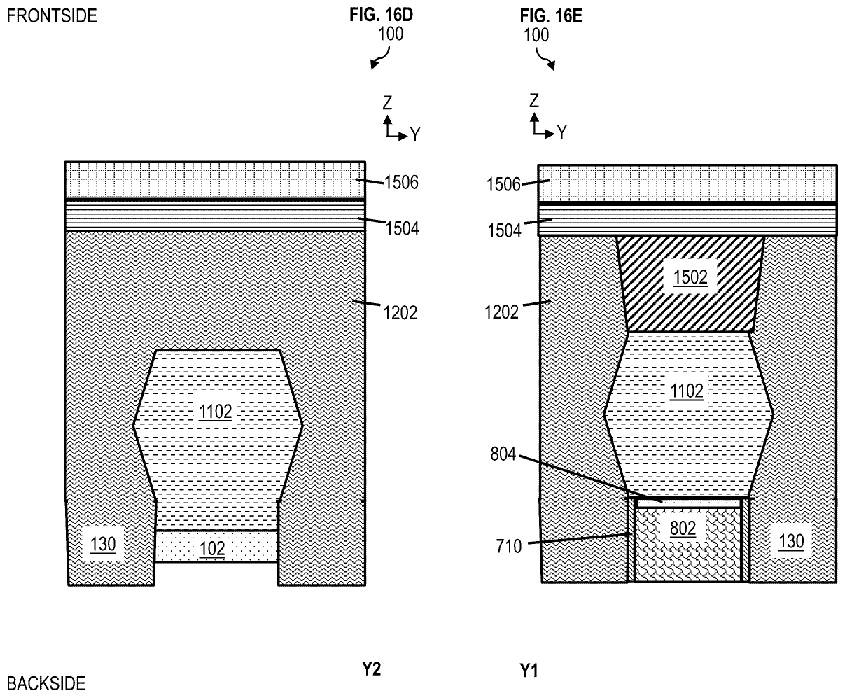

FIGS. 16A, 16B, 16C, 16D, and 16E depict the IC 100 after wafer flip and removal of the lower substrate and etch stop layer. The wafer is flipped, and processing continues on the backside of the semiconductor structure. For consistency and to assist the reader, the wafer is not illustrated as being flipped in the figures, although it is understood that the wafer is flipped with fabrication processing performed on the backside.

The lower substrate 101 is removed to expose the etch stop layer 104. Etching and/or chemical mechanical polishing/planarization (CMP) may be utilized to remove the lower substrate 101. Etching can be performed to remove the etch stop layer 104. Also, etching is performed to remove a portion of the substrate 102, thereby exposing the placeholder 802.

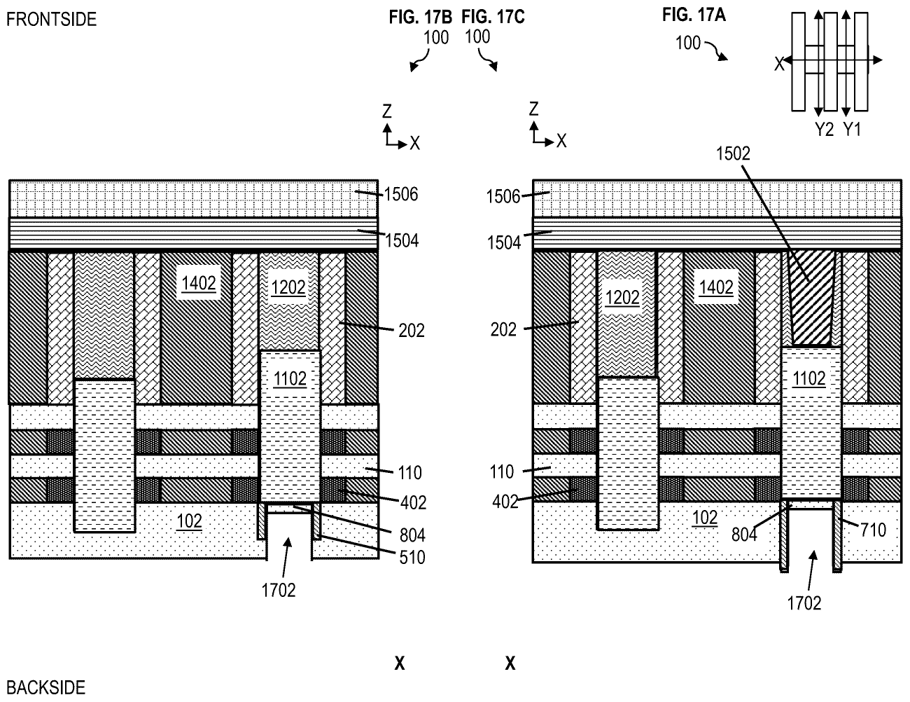

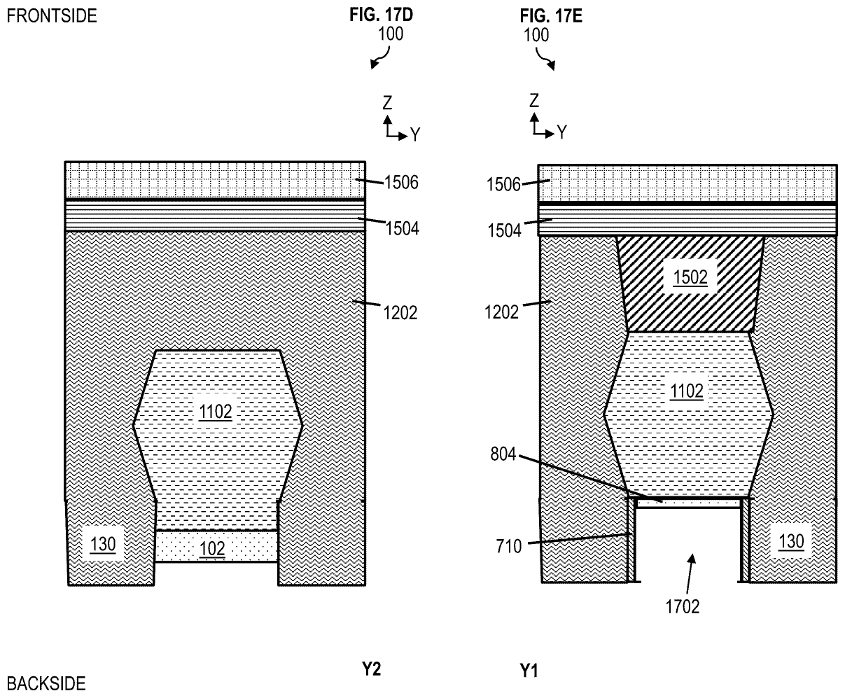

FIGS. 17A, 17B, 17C, 17D, and 17E depict the IC 100 after placeholder removal. Etching is performed to selectively remove the placeholder 802, thereby exposing the layer 804 and forming a cavity 1702. In FIG. 17C, the liner 710 extends the length of the cavity 1702. In one or more embodiments, the liner 710 may extend beyond the bottom surface of the substrate 102. In the alterative process depicted in FIG. 17B, the liner 510 is shorter than the liner 710 and extends less than the length of the cavity 1702.

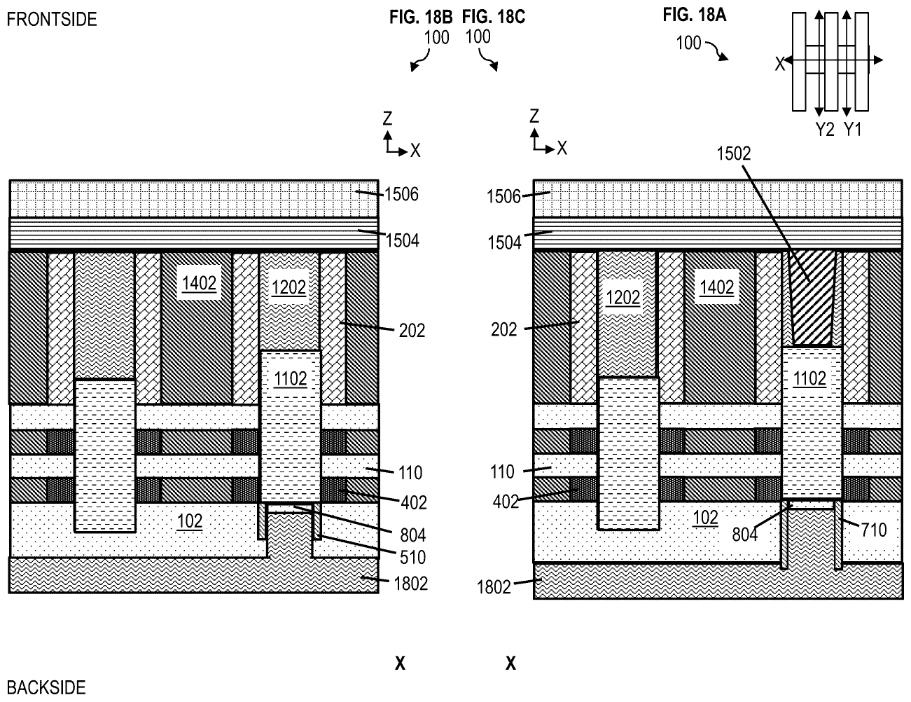

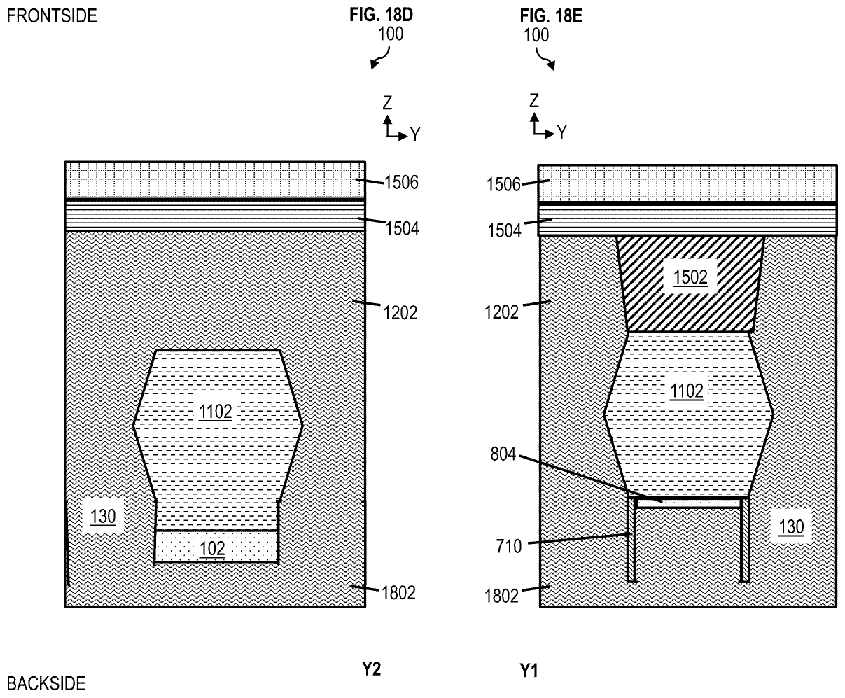

FIGS. 18A, 18B, 18C, 18D, and 18E depict the IC 100 after depositing fill material. Additional material of fill layer 1802 is deposited on the backside, which fills in cavity 1702. The fill layer 1802 may be formed of oxide materials, such as silicon dioxide, aluminum oxide, etc. The fill layer 1802 may be a low-k dielectric material, an ultra-low-k dielectric material, etc. The fill layer 1802 may be considered a backside ILD. The liners 510 and 710 are on the sidewalls of the fill layer 1802 under one of the source/drain regions 1102. The liners 510 and 710 are adjacent to an inner spacer 402, while both the inner spacer 402 and the liners 510 and 710 are adjacent to the same one of the source/drain regions 1102. In one or more embodiments, the combination of the inner spacer 402 and the liners 510 and 710 form an L-shaped protective barrier for the same one of the source/drain regions 1102.

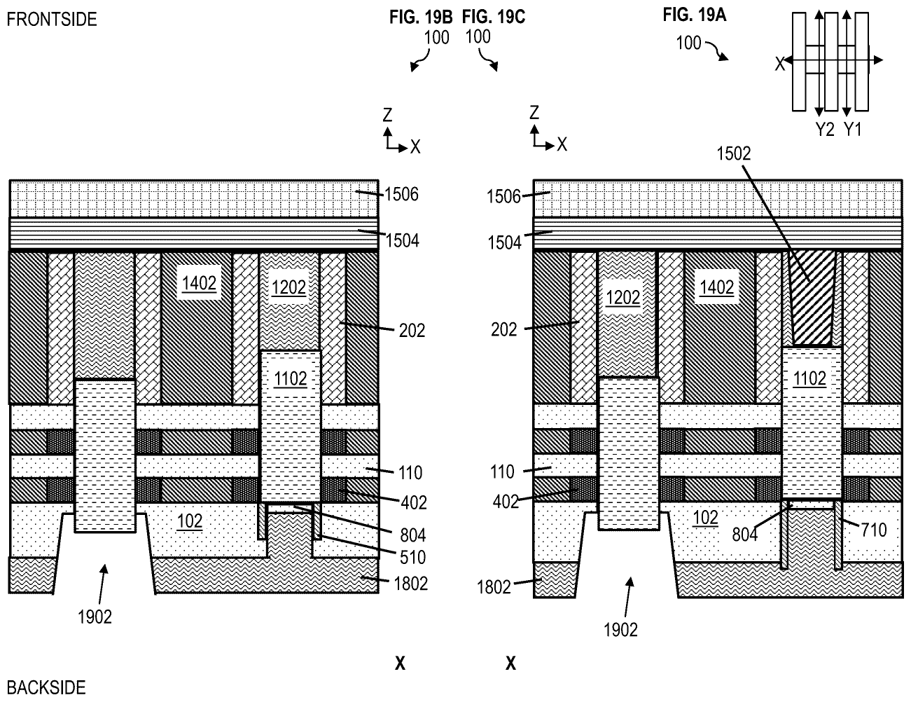

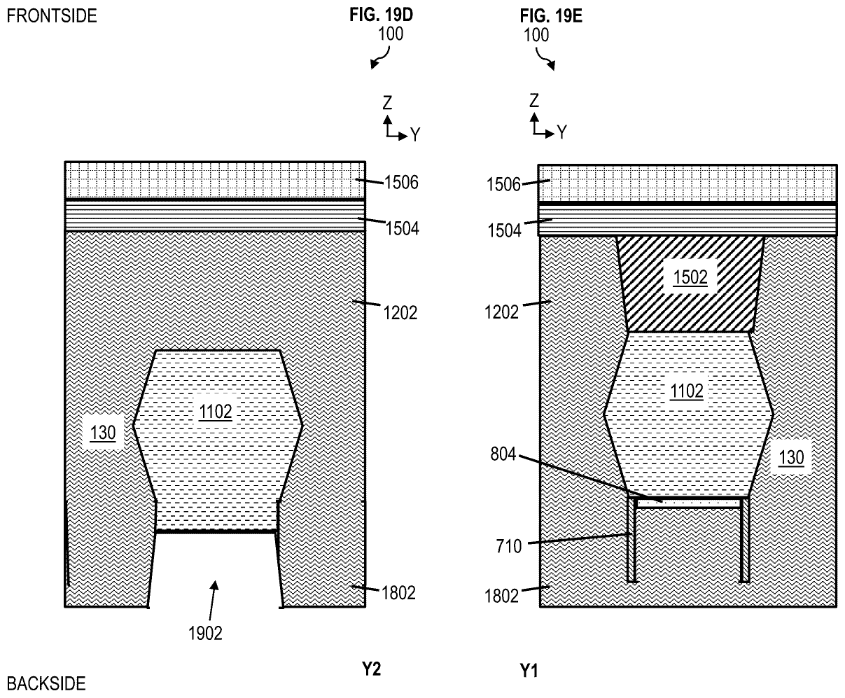

FIGS. 19A, 19B, 19C, 19D, and 19E depict the IC 100 after opening cavities for backside source/drain contacts. Lithography is performed to etch a cavity 1902 that exposes the backside of one of the source/drain regions 1102. As can be recognized, the other one of the source/drain regions 1102 has the liners 510 and 710 as protection.

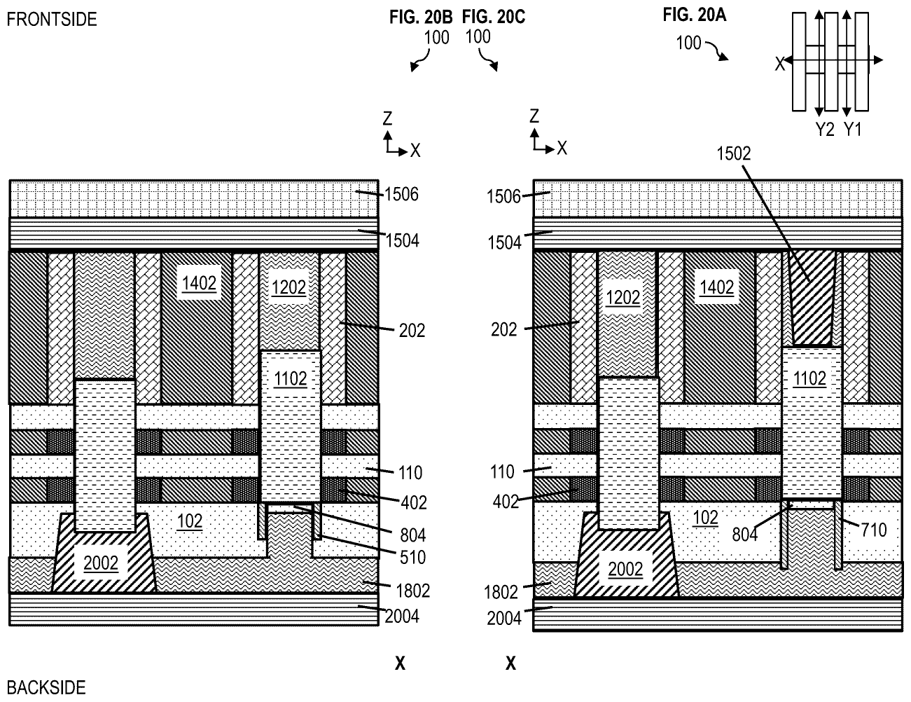

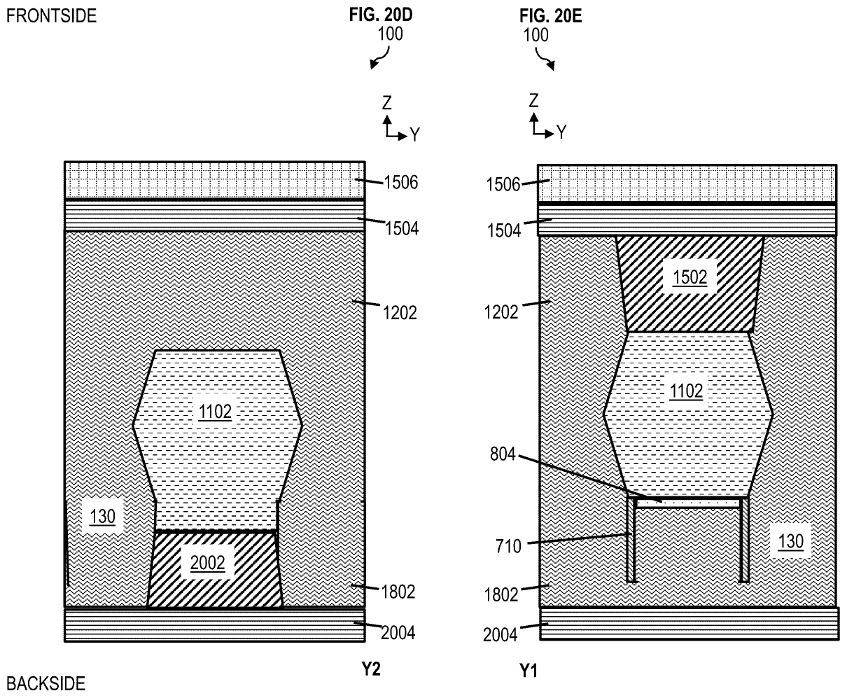

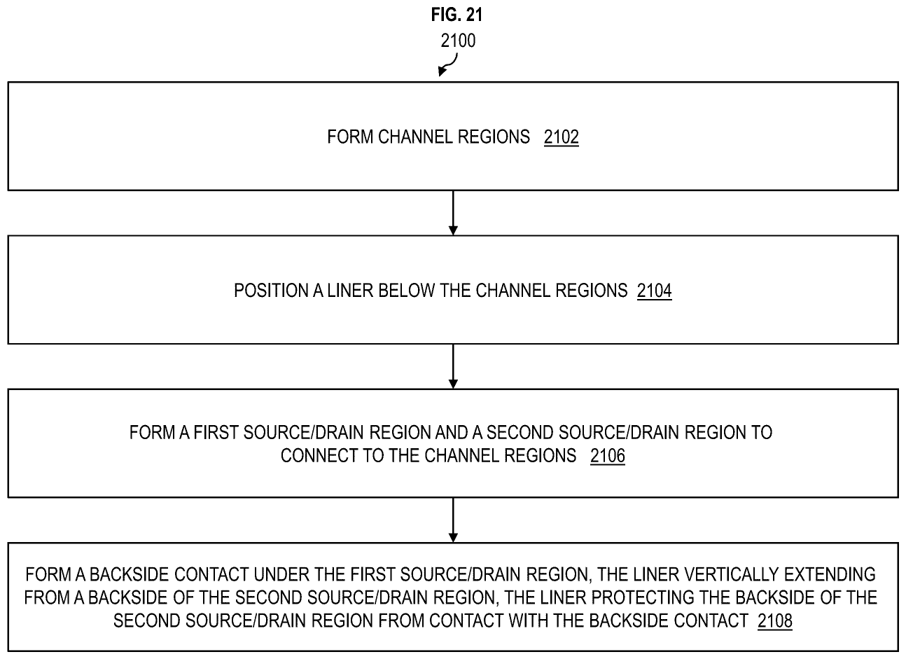

FIGS. 20A, 20B, 20C, 20D, and 20E depict the IC 100 after contact formation and BEOL formation. Lithography is performed to form cavities, and conductive material is deposited to form bottom source/drain contacts 2002 which are backside contacts. The contacts may be referred to as metal contacts. Example conductive materials of the contacts can include tungsten, titanium, titanium nitride, aluminum, nickel, chromium, copper, gold, etc., along with various combinations and liners. Although not shown, silicide may be formed during the deposition of the conductive material. A backside power delivery network (BSPDN) 2004 is formed on the bottom source/drain contacts 2002 for signal and power distribution.

FIG. 21 depicts a flowchart of a computer-implemented method 2100 of forming a semiconductor structure with a backside contact and backside isolation in accordance with one or more embodiments. Reference can be made to any figures discussed herein.

At blocks 2102 and 2104, the method 2100 includes forming channel regions (e.g., semiconductor layers 110) and positioning a liner (e.g., liners 510 and 710) below the channel regions. At block 2106, the method 2100 includes forming a first source/drain region and a second source/drain region (e.g., source/drain regions 1102) to connect to the channel regions (e.g., semiconductor layers 110). At block 2108, the method 2100 includes forming a backside contact (e.g., bottom source/drain contact 2002) under the first source/drain region, the liner (e.g., liners 510 and 710) vertically extending from a backside of the second source/drain region, the liner (e.g., liners 510 and 710) protecting the backside of the second source/drain region (e.g., one of the source/drain regions 1102) from contact with the backside contact (e.g., bottom source/drain contact 2002).

The liner (e.g., liners 510 and 710) include non-conductive material. The liner intervenes between the backside of the second source/drain region (e.g., one of the source/drain regions 1102) and the backside contact (e.g., bottom source/drain contact 2002). Fill material (e.g., fill layer 1802) is under the second source/drain region and the liner is on a side of the fill material (e.g., fill layer 1802). The liner is self-aligned to the second source/drain region. The liner and the second source/drain region are both formed in an opening (e.g., opening 210), thereby being self-aligned.

The second source/drain region (e.g., one of the source/drain regions 1102) is formed at a different level from the first source/drain region (e.g., another one of the source/drain regions 1102), as a result of the liner being positioned under the second source/drain region. The liner (e.g., liners 510 and 710) is adjacent to an inner spacer (e.g., inner spacers 402), the inner spacer and the liner being adjacent to the second source/drain region (e.g., one of the source/drain regions 1102).

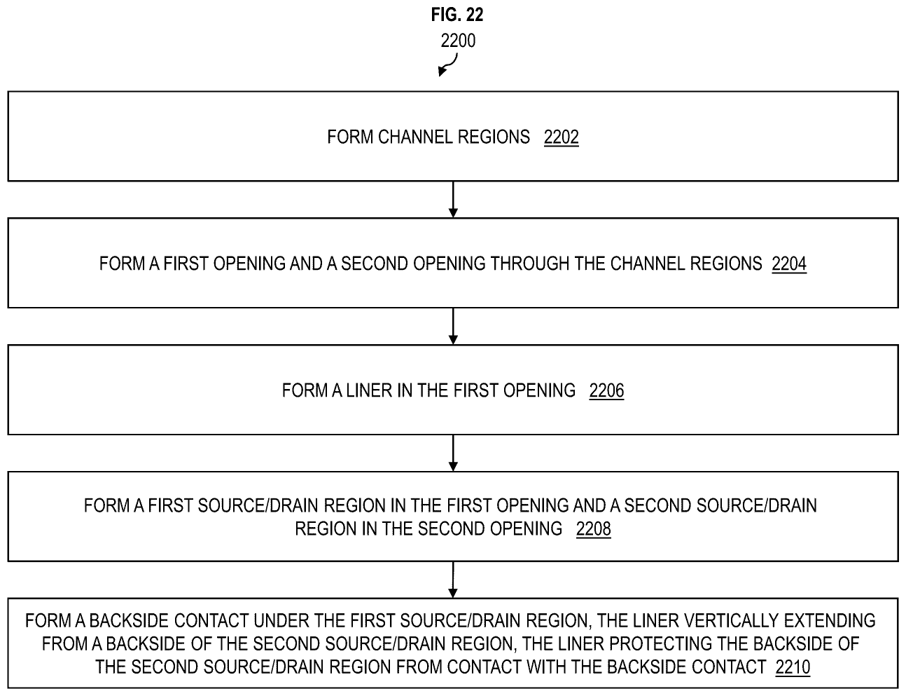

FIG. 22 depicts a flowchart of a computer-implemented method 2200 of forming a semiconductor structure with a backside contact and backside isolation in accordance with one or more embodiments. Reference can be made to any figures discussed herein.

At blocks 2202, 2204, and 2206, the method 2200 includes forming channel regions (e.g., semiconductor layers 110) and forming a first opening and a second opening (e.g., openings 210) through the channel regions, and forming a liner (e.g., liners 510 and 710) in the first opening (e.g., one of the openings 210). At block 2208, the method 2200 includes forming a first source/drain region in the first opening (e.g., one of the source/drain regions 1102 in one of the openings 210) and a second source/drain region in the second opening (e.g., another one of the source/drain regions 1102 in another one of the openings 210). At block 2210, the method 2200 includes forming a backside contact (e.g., bottom source/drain contact 2002) under the first source/drain region, the liner (e.g., liners 510 and 710) vertically extending from a backside of the second source/drain region, the liner (e.g., liners 510 and 710) protecting the backside of the second source/drain region (e.g., one of the source/drain regions 1102) from contact with the backside contact (e.g., bottom source/drain contact 2002).

As discussed herein, gate material is formed around the semiconductor layers. The gate material includes high-k material and work function material generally referred to as a high-k metal gate (HKMG). Techniques for forming HKMG in gate openings are well-known in the art and, thus, the details have been omitted in order to allow the reader to focus on the salient aspects of the disclosed methods. However, it should be understood that such HKMG will generally include formation of one or more gate dielectric layers (e.g., an inter-layer (IL) oxide and a high-k gate dielectric layer), which are deposited so as to line the gate openings, and formation of one or more metal layers, which are deposited onto the gate dielectric layer(s) so as to fill the gate openings. The materials and thicknesses of the dielectric and metal layers used for the HKMG can be preselected to achieve desired work functions given the conductivity type of the FET. To avoid clutter in the drawings and to allow the reader to focus on the salient aspects of the disclosed methods, the different layers within the HKMG stack are not illustrated. For explanation purposes, a high-k gate dielectric layer can be, for example, a dielectric material with a dielectric constant that is greater than the dielectric constant of silicon dioxide (i.e., greater than 3.9). Exemplary high-k dielectric materials include, but are not limited to, hafnium (Hf)-based dielectrics (e.g., hafnium oxide, hafnium silicon oxide, hafnium silicon oxynitride, hafnium aluminum oxide, etc.) or other suitable high-k dielectrics (e.g., aluminum oxide, tantalum oxide, zirconium oxide, etc.). Optionally, the metal layer(s) can include a work function metal that is immediately adjacent to the gate dielectric layer and that is preselected in order to achieve an optimal gate conductor work function given the conductivity type of the nanosheet-FET. For example, the optimal gate conductor work function for the PFETs can be, for example, between about 4.9 eV and about 5.2 eV. Exemplary metals (and metal alloys) having a work function within or close to this range include, but are not limited to, ruthenium, palladium, platinum, cobalt, and nickel, as well as metal oxides (aluminum carbon oxide, aluminum titanium carbon oxide, etc.) and metal nitrides (e.g., titanium nitride, titanium silicon nitride, tantalum silicon nitride, titanium aluminum nitride, tantalum aluminum nitride, etc.). The optimal gate conductor work function for NFETs can be, for example, between 3.9 eV and about 4.2 eV. Exemplary metals (and metal alloys) having a work function within or close to this range include, but are not limited to, hafnium, zirconium, titanium, tantalum, aluminum, and alloys thereof, such as, hafnium carbide, zirconium carbide, titanium carbide, tantalum carbide, and aluminum carbide. The metal layer(s) can further include a fill metal or fill metal alloy, such as tungsten, a tungsten alloy (e.g., tungsten silicide or titanium tungsten), cobalt, aluminum, or any other suitable fill metal or fill metal.

Although not shown in detail, contact formation and ILD formation are performed. As such, ILD material can be deposited, source/drain contact openings are patterned by conventional lithography, and then metal is deposited to fill the cavities thereby forming metal contacts. A portion of the metal contacts may include silicide, resulting from the interface of the metal material and semiconductor material. The metal contacts are source/drain contacts that are respectively connected to epitaxial source/drain regions.

The ILD material can be SiO₂, SiN, a low-k dielectric material or an ultra-low-k dielectric material. Low-k dielectric materials may generally include dielectric materials having a k value of about 3.9 or less. The ultra-low-k dielectric material generally includes dielectric materials having a k value less than 2.5. Unless otherwise noted, all k values mentioned in the present application are measured relative to a vacuum. Exemplary ultra-low-k dielectric materials generally include porous materials such as porous organic silicate glasses, porous polyamide nanofoams, silica xerogels, porous hydrogen silsequioxane (HSQ), porous methylsilsesquioxane (MSQ), porous inorganic materials, porous CVD materials, porous organic materials, or combinations thereof. The ultra-low-k dielectric material can be produced using a templated process or a sol-gel process as is generally known in the art. In the templated process, the precursor typically contains a composite of thermally labile and stable materials. After film deposition, the thermally labile materials can be removed by thermal heating, leaving pores in the dielectric film. In the sol gel process, the porous low-k dielectric films can be formed by hydrolysis and polycondensation of an alkoxide(s) such as tetraetehoxysilane (TEOS).

Various embodiments of the present invention are described herein with reference to the related drawings. Alternative embodiments can be devised without departing from the scope of this invention. Although various connections and positional relationships (e.g., over, below, adjacent, etc.) are set forth between elements in the following description and in the drawings, persons skilled in the art will recognize that many of the positional relationships described herein are orientation-independent when the described functionality is maintained even though the orientation is changed. These connections and/or positional relationships, unless specified otherwise, can be direct or indirect, and the present invention is not intended to be limiting in this respect. Accordingly, a coupling of entities can refer to either a direct or an indirect coupling, and a positional relationship between entities can be a direct or indirect positional relationship. As an example of an indirect positional relationship, references in the present description to forming layer “A” over layer “B” include situations in which one or more intermediate layers (e.g., layer “C”) is between layer “A” and layer “B” as long as the relevant characteristics and functionalities of layer “A” and layer “B” are not substantially changed by the intermediate layer(s).

The phrase “selective to,” such as, for example, “a first element selective to a second element,” means that the first element can be etched and the second element can act as an etch stop.

As used herein, “p-type” refers to the addition of impurities to an intrinsic semiconductor that creates deficiencies of valence electrons. In a silicon-containing substrate, examples of p-type dopants, i.e., impurities, include but are not limited to: boron, aluminum, gallium and indium.

As used herein, “n-type” refers to the addition of impurities that contributes free electrons to an intrinsic semiconductor. In a silicon containing substrate examples of n-type dopants, i.e., impurities, include but are not limited to antimony, arsenic and phosphorous.

As previously noted herein, for the sake of brevity, conventional techniques related to semiconductor device and integrated circuit (IC) fabrication may or may not be described in detail herein. By way of background, however, a more general description of the semiconductor device fabrication processes that can be utilized in implementing one or more embodiments of the present invention will now be provided. Although specific fabrication operations used in implementing one or more embodiments of the present invention can be individually known, the described combination of operations and/or resulting structures of the present invention are unique. Thus, the unique combination of the operations described in connection with the fabrication of a semiconductor device according to the present invention utilize a variety of individually known physical and chemical processes performed on a semiconductor (e.g., silicon) substrate, some of which are described in the immediately following paragraphs.

In general, the various processes used to form a micro-chip that will be packaged into an IC fall into four general categories, namely, film deposition, removal/etching, semiconductor doping and patterning/lithography. Deposition is any process that grows, coats, or otherwise transfers a material onto the wafer. Available technologies include physical vapor deposition (PVD), chemical vapor deposition (CVD), electrochemical deposition (ECD), molecular beam epitaxy (MBE) and more recently, atomic layer deposition (ALD) among others. Removal/etching is any process that removes material from the wafer. Examples include etch processes (either wet or dry), and chemical-mechanical planarization (CMP), and the like. Semiconductor doping is the modification of electrical properties by doping, for example, transistor sources and drains, generally by diffusion and/or by ion implantation. These doping processes are followed by furnace annealing or by rapid thermal annealing (RTA). Annealing serves to activate the implanted dopants. Films of both conductors (e.g., poly-silicon, aluminum, copper, etc.) and insulators (e.g., various forms of silicon dioxide, silicon nitride, etc.) are used to connect and isolate transistors and their components. Selective doping of various regions of the semiconductor substrate allows the conductivity of the substrate to be changed with the application of voltage. By creating structures of these various components, millions of transistors can be built and wired together to form the complex circuitry of a modern microelectronic device.

As noted above, atomic layer etching processes can be used in the present invention for via residue removal, such as can be caused by via misalignment. The atomic layer etch process provide precise etching of metals using a plasma-based approach or an electrochemical approach. The atomic layer etching processes are generally defined by two well-defined, sequential, self-limiting reaction steps that can be independently controlled. The process generally includes passivation followed selective removal of the passivation layer and can be used to remove thin metal layers on the order of nanometers. An exemplary plasma-based approach generally includes a two-step process that generally includes exposing a metal such a copper to chlorine and hydrogen plasmas at low temperature (below 20° C.). This process generates a volatile etch product that minimizes surface contamination. In another example, cyclic exposure to an oxidant and hexafluoroacetylacetone (Hhfac) at an elevated temperature such as at 275° C. can be used to selectively etch a metal such as copper. An exemplary electrochemical approach also can include two steps. A first step includes surface-limited sulfidization of the metal such as copper to form a metal sulfide, e.g., Cu₂S, followed by selective wet etching of the metal sulfide, e.g., etching of Cu₂S in HCl. Atomic layer etching is relatively recent technology and optimization for a specific metal is well within the skill of those in the art. The reactions at the surface provide high selectivity and minimal or no attack of exposed dielectric surfaces.

Semiconductor lithography is the formation of three-dimensional relief images or patterns on the semiconductor substrate for subsequent transfer of the pattern to the substrate. In semiconductor lithography, the patterns are formed by a light sensitive polymer called a photoresist. To build the complex structures that make up a transistor and the many wires that connect the millions of transistors of a circuit, lithography and etch pattern transfer steps are repeated multiple times. Each pattern being printed on the wafer is aligned to the previously formed patterns and slowly the conductors, insulators and selectively doped regions are built up to form the final device.

The photoresist can be formed using conventional deposition techniques such chemical vapor deposition, plasma vapor deposition, sputtering, dip coating, spin-on coating, brushing, spraying and other like deposition techniques can be employed. Following formation of the photoresist, the photoresist is exposed to a desired pattern of radiation such as X-ray radiation, extreme ultraviolet (EUV) radiation, electron beam radiation or the like. Next, the exposed photoresist is developed utilizing a conventional resist development process.

After the development step, the etching step can be performed to transfer the pattern from the patterned photoresist into the interlayer dielectric. The etching step used in forming at least one opening can include a dry etching process (including, for example, reactive ion etching, ion beam etching, plasma etching or laser ablation), a wet chemical etching process or any combination thereof.

For the sake of brevity, conventional techniques related to making and using aspects of the invention may or may not be described in detail herein. In particular, various aspects of computing systems and specific computer programs to implement the various technical features described herein are well known. Accordingly, in the interest of brevity, many conventional implementation details are only mentioned briefly herein or are omitted entirely without providing the well-known system and/or process details.

In some embodiments, various functions or acts can take place at a given location and/or in connection with the operation of one or more apparatuses or systems. In some embodiments, a portion of a given function or act can be performed at a first device or location, and the remainder of the function or act can be performed at one or more additional devices or locations.

The terminology used herein is for the purpose of describing particular embodiments only and is not intended to be limiting. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, element components, and/or groups thereof.

The corresponding structures, materials, acts, and equivalents of all means or step plus function elements in the claims below are intended to include any structure, material, or act for performing the function in combination with other claimed elements as specifically claimed. The present disclosure has been presented for the purposes of illustration and description but is not intended to be exhaustive or limited to the form disclosed. Many modifications and variations will be apparent to those of ordinary skill in the art without departing from the scope and spirit of the disclosure. The embodiments were chosen and described in order to best explain the principles of the disclosure and the practical application, and to enable others of ordinary skill in the art to understand the disclosure for various embodiments with various modifications as are suited to the particular use contemplated.

The diagrams depicted herein are illustrative. There can be many variations to the diagrams or the steps (or operations) described therein without departing from the spirit of the disclosure. For instance, the actions can be performed in a differing order or actions can be added, deleted or modified. Also, the term “coupled” describes having a signal path between two elements and does not imply a direct connection between the elements with no intervening elements/connections therebetween. All of these variations are considered a part of the present disclosure.

The following definitions and abbreviations are to be used for the interpretation of the claims and the specification. As used herein, the terms “comprises,” “comprising,” “includes,” “including,” “has,” “having,” “contains” or “containing,” or any other variation thereof, are intended to cover a non-exclusive inclusion. For example, a composition, a mixture, process, method, article, or apparatus that comprises a list of elements is not necessarily limited to only those elements but can include other elements not expressly listed or inherent to such composition, mixture, process, method, article, or apparatus.

Additionally, the term “exemplary” is used herein to mean “serving as an example, instance or illustration.” Any embodiment or design described herein as “exemplary” is not necessarily to be construed as preferred or advantageous over other embodiments or designs. The terms “at least one” and “one or more” are understood to include any integer number greater than or equal to one, i.e., one, two, three, four, etc. The terms “a plurality” are understood to include any integer number greater than or equal to two, i.e., two, three, four, five, etc. The term “connection” can include both an indirect “connection” and a direct “connection.”

The terms “about,” “substantially,” “approximately,” and variations thereof, are intended to include the degree of error associated with measurement of the particular quantity based upon the equipment available at the time of filing the application. For example, “about” can include a range of ±8% or 5%, or 2% of a given value.

The descriptions of the various embodiments of the present invention have been presented for purposes of illustration but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments described herein.

What is claimed is:

1. A semiconductor structure comprising:
channel regions connected to a first source/drain region and a second source/drain region;
a backside contact disposed under the first source/drain region; and
a liner vertically extending from a backside of the second source/drain region, the liner protecting the backside of the second source/drain region from contact with the backside contact.

2. The semiconductor structure of claim 1, wherein the liner comprises non-conductive material.

3. The semiconductor structure of claim 1, wherein the liner intervenes between the backside of the second source/drain region and the backside contact.

4. The semiconductor structure of claim 1, wherein fill material is under the second source/drain region and the liner is on a side of the fill material.

5. The semiconductor structure of claim 1, wherein the liner is self-aligned to the second source/drain region.

6. The semiconductor structure of claim 1, wherein the liner and the second source/drain region are both formed in an opening, thereby being self-aligned.

7. The semiconductor structure of claim 1, wherein the second source/drain region is formed at a different level from the first source/drain region, as a result of the liner being positioned under the second source/drain region.

8. The semiconductor structure of claim 1, wherein the liner is adjacent to an inner spacer, the inner spacer and the liner being adjacent to the second source/drain region.

9. A method comprising:
forming channel regions;
positioning a liner below the channel regions;
forming a first source/drain region and a second source/drain region to connect to the channel regions; and
forming a backside contact under the first source/drain region, the liner vertically extending from a backside of the second source/drain region, the liner protecting the backside of the second source/drain region from contact with the backside contact.

10. The method of claim 9, wherein the liner comprises non-conductive material.

11. The method of claim 9, wherein the liner intervenes between the backside of the second source/drain region and the backside contact.

12. The method of claim 9, wherein fill material is under the second source/drain region and the liner is on a side of the fill material.

13. The method of claim 9, wherein the liner is self-aligned to the second source/drain region.

14. The method of claim 9, wherein the liner and the second source/drain region are both formed in an opening, thereby being self-aligned.

15. The method of claim 9, wherein the second source/drain region is formed at a different level from the first source/drain region, as a result of the liner being positioned under the second source/drain region.

16. The method of claim 9, wherein the liner is adjacent to an inner spacer, the inner spacer and the liner being adjacent to the second source/drain region.

17. A method comprising:
forming channel regions;
forming a first opening and a second opening through the channel regions;
forming a liner in the first opening;
forming a first source/drain region in the first opening and a second source/drain region in the second opening; and
forming a backside contact under the first source/drain region, the liner vertically extending from a backside of the second source/drain region, the liner protecting the backside of the second source/drain region from contact with the backside contact.

18. The method of claim 17, wherein the liner comprises non-conductive material.

19. The method of claim 17, wherein fill material is under the second source/drain region and the liner is on a side of the fill material.

20. The method of claim 17, wherein the liner is self-aligned to the second source/drain region by being formed in the first opening.
